(19) United States
(12) Patent Application Publication
(10) Pub. No.: US 2019/0219645 A1
(43) Pub. Date: Jul. 18, 2019

(54) COMPACT MAGNETOMETER APPARATUS

(71) Applicant: LOCKHEED MARTIN CORPORATION, Bethesda, MD (US)

(72) Inventors: Joseph W. HAHN, Erial, NJ (US); Wilbur LEW, Mount Laurel, NJ (US); Andrew Raymond MANDEVILLE, Philadelphia, PA (US); Yongdan HU, Bothell, WA (US)

(21) Appl. No.: 16/246,705

(22) Filed: Jan. 14, 2019

Related U.S. Application Data
(60) Provisional application No. 62/617,033, filed on Jan. 12, 2018.

(51) Int. Cl. G01R 33/26

(52) U.S. Cl. CPC G01R 33/26

(57) ABSTRACT

A magnetometer for magnetic detection includes a magneto-optical defect center material comprising at least one magneto-optical defect center that emits an optical signal when excited by an excitation light, a radio frequency (RF) exciter system configured to provide RF excitation to the magneto-optical defect center material; an optical excitation system configured to direct the excitation light to the magneto-optical defect center material; an optical detector configured to receive the optical signal emitted by the magneto-optical defect center material based on the excitation light and the RF excitation; a magnetic field generator configured to generate a magnetic field detected at the magneto-optical defect center material; and a housing configured to enclose the magneto-optical defect center material, the RF exciter system, the optical excitation system, the optical detector, and the magnetic field generator. The housing is hermetically sealed.

### CROSS-REFERENCE TO RELATED APPLICATIONS

The present application claims the benefit of and priority to U.S. Provisional Patent Application No. 62/617,033, filed on Jan. 12, 2018, which is incorporated by reference herein in its entirety.

### FIELD

The present disclosure relates, in general, to magnetometers using magneto-optical defect center materials, and more particularly, to magnetometers including a nitrogen vacancy diamond material.

### BACKGROUND

The following description is provided to assist the understanding of the reader. None of the information provided or references cited is admitted to be prior art. Some magnetometers use magneto-optical defect center materials to determine a magnetic field. Such magnetometers can direct light into the magneto-optical defect center material. Some magneto-optical defect center materials with defect centers can be used to sense an applied magnetic field by transmitting light into the materials and measuring the responsive light that is emitted.

A number of industrial and scientific areas such as physics and chemistry can benefit from magnetic detection and imaging with a device that has improved sensitivity and/or the ability to capture signals that fluctuate rapidly (i.e., improved bandwidth) with a package that is small in size, efficient in power and reduced in volume. Some advanced magnetic imaging systems can operate in restricted conditions, for example, high vacuum and/or cryogenic temperatures, which can make them inapplicable for imaging applications that require ambient or other conditions. Furthermore, small size, weight and power (SWAP) magnetic sensors of moderate sensitivity, vector accuracy, and bandwidth may be valuable in some applications.

### SUMMARY

According to some examples, a magnetometer for magnetic detection may include a magneto-optical defect center material comprising at least one magneto-optical defect center that emits an optical signal when excited by an excitation light; a radio frequency (RF) exciter system configured to provide RF excitation to the magneto-optical defect center material; an optical excitation system configured to direct the excitation light to the magneto-optical defect center material, the optical excitation system including an optical light source; an optical detector configured to receive the optical signal emitted by the magneto-optical defect center material based on the excitation light and the RF excitation; a magnetic field generator configured to generate a magnetic field detected at the magneto-optical defect center material; and a housing configured to enclose the magneto-optical defect center material, the RF exciter system, the optical excitation system, the optical detector, and the magnetic field generator, wherein the housing may be hermetically sealed.

In some aspects, an overall size of the magnetometer may be reduced in accordance with the following method steps including: 1) reducing a size of each individual component, 2) utilizing a hermetically sealed housing that allows for elimination of purge gas components/gaskets, 3) removing optical adjustment mechanisms from the interior of the housing of the magnetometer and adding the optical adjustment mechanisms to the tooling/fixturing used only during assembly of the magnetometer, 4) using a Helmholtz pair of bias magnets to maintain the bias field uniformity even as the size of the magnetometer is reduced, and/or 5) relying on unique optics for focusing and polarization of the laser diode including using prealigned/prefabricated microlenses and incorporating a waveplate in the diode housing or at an output of the diode housing.

According to some examples, a system for magnetic detection includes a magnetometer comprising: a magneto-optical defect center material comprising at least one magneto-optical defect center that emits an optical signal when excited by an excitation light; a radio frequency (RF) exciter system configured to provide RF excitation to the magneto-optical defect center material; an optical excitation system configured to direct the excitation light to the magneto-optical defect center material, the optical excitation system including an optical light source; an optical detector configured to receive the optical signal emitted by the magneto-optical defect center material based on the excitation light and the RF excitation; a magnetic field generator configured to generate a magnetic field detected at the magneto-optical defect center material; and a housing configured to enclose the magneto-optical defect center material, the RF exciter system, the optical excitation system, the optical detector, and the magnetic field generator, the housing being hermetically sealed; and optical adjustment mechanisms may be external to the housing, the optical adjustment mechanisms configured to adjust a position of the optical light source and/or the optical detector.

According to some examples, a housing for a magnetometer including a magneto-optical defect center material, an RF exciter system, an optical excitation system, an optical detector, and a magnetic field generator, includes a shell portion; a first lid fixed to an upper surface of the shell portion; and a second lid fixed to a lower surface of the shell portion, wherein the housing is hermetically sealed.

According to some examples, a magnetic field generator for a magnetometer may include a magneto-optical defect center material, an RF exciter system, an optical excitation system, and an optical detector including a plurality of permanent magnets arranged in a Halbach array. In some aspects, the Halbach array includes a first mounting frame provided above the magneto-optical defect center material, the RF exciter system, the optical excitation system, and the optical detector; and a second mounting frame provided below the magneto-optical defect center material, the RF exciter system, the optical excitation system, and the optical detector, each of the first mounting frame and the second mounting frame configured to receive a plurality of permanent magnets therein.

According to some examples, an optical system for a magnetometer may include an optical excitation system configured to direct excitation light to a target, the optical excitation system including an optical light source; and an optical waveguide assembly comprising an optical waveguide with a hollow core and at least one optical filter coating, wherein the optical waveguide assembly may be configured to transmit light emitted from the target to an optical detector through the at least one optical filter coating, wherein the optical excitation system and the optical waveguide assembly may be disposed within a diode housing.

According to some examples, an optical system for a magnetometer may include an optical excitation system configured to direct excitation light to a target, the optical excitation system including an optical light source; and an optical waveguide assembly may comprise an optical waveguide with a hollow core and at least one optical filter coating, wherein the optical waveguide assembly may be configured to transmit light emitted from the target to an optical detector through the at least one optical filter coating, wherein the optical excitation system may be disposed within a diode housing, and the optical waveguide assembly may be mounted to an output of the diode housing.

The foregoing summary is illustrative only and is not intended to be in any way limiting. In addition to the illustrative aspects, examples, and features described above, further aspects, examples, and features will become apparent by reference to the following drawings and the detailed description.

### BRIEF DESCRIPTION OF THE DRAWINGS

FIG. 1 illustrates one orientation of a Nitrogen-Vacancy (NV) center in a diamond lattice.

FIG. 2 illustrates an energy level diagram showing energy levels of spin states for the NV center.

FIG. 3A is a schematic diagram illustrating a NV center magnetic sensor system.

FIG. 3B is a schematic diagram illustrating a NV center magnetic sensor system with a waveplate in accordance with some illustrative examples.

FIG. 4 is a graph illustrating the fluorescence as a function of an applied RF frequency of an NV center along a given direction for a zero magnetic field, and also for a non-zero magnetic field having a component along the NV axis.

FIG. 5A is a schematic illustrating a Ramsey sequence of optical excitation pulses and RF excitation pulses.

FIG. 5B is a graph illustrating the fluorescence as a function of an applied RF frequency for four different NV center orientations for a non-zero magnetic field.

FIG. 6A is a schematic diagram illustrating some examples of a magnetic field detection system.

FIG. 6B is another schematic diagram illustrating some examples of a magnetic field detection system.

FIG. 6C is another schematic diagram illustrating some examples of a magnetic field detection system.

FIG. 7 illustrates a top view of a housing of a magnetometer in accordance with some illustrative examples. Although the top lid is illustrated, one of ordinary skill in the art would understand that the bottom lid has the same configuration when viewed for a bottom view. FIG. 7 further includes side views of the housing from different positions along a circumference of the housing.

FIG. 8 illustrates a top perspective view and a bottom perspective view of the magnetometer of FIG. 7 with the top lid and the bottom lid removed.

FIG. 9 illustrates a top view of the magnetometer of FIG. 7 with the top lid and magnetic field generator removed.

FIG. 10 illustrates a top perspective view of optical components of the magnetometer of FIG. 7.

FIG. 11 illustrates a cross-section view of the optical components of FIG. 10.

FIG. 12 illustrates a cross-sectional view from the side of the magnetometer of FIG. 7.

FIG. 13 illustrates other embodiments of a mounting frame of a magnetic field generator of the magnetometer of FIG. 7.

FIG. 14 illustrates examples of a uniform magnetic field generated by the magnetic field generator of FIG. 14.

FIGS. 15A and 15B illustrate some different views of the mounting frame of FIG. 14 and a magneto-optical defect center material mounted to a base with the magneto-optical defect center material provided offset from a center of the mounting frame.

FIG. 16 illustrates an optical excitation assembly of the magnetometer of FIG. 7 as a cross-section including light pipes in some examples.

FIG. 17 illustrates a light pipe with body mount in some examples.

FIG. 18 illustrates an RF amplifier module including a plurality of individually packaged chips attached to a printed circuit board.

It will be recognized that some or all of the figures are schematic representations for purposes of illustration. The figures are provided for the purpose of illustrating one or more examples with the explicit understanding that they will not be used to limit the scope or the meaning of the claims.

### DETAILED DESCRIPTION

In the following detailed description, reference is made to the accompanying drawings, which form a part hereof In the drawings, similar symbols typically identify similar components, unless context dictates otherwise. The illustrative examples described in the detailed description, drawings, and claims are not meant to be limiting. Other examples may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Atomic-sized magneto-optical defect centers, such as nitrogen-vacancy (NV) centers in diamond lattices, can have excellent sensitivity for magnetic field measurement and enable fabrication of small magnetic sensors. Magneto-optical defect center materials include but are not be limited to diamonds, Silicon Carbide (SiC), Phosphorous, and other materials with nitrogen, boron, carbon, silicon, or other defect centers. Diamond nitrogen vacancy (DNV) sensors may be maintained in room temperature and atmospheric pressure and can be even used in liquid environments. A green optical source (e.g., a micro-LED) can optically excite NV centers of the DNV sensor and cause emission of fluorescence radiation (e.g., red light) under off-resonant optical excitation. A magnetic field generated, for example, by a microwave coil can probe triplet spin states (e.g., with ms=−1, 0, +1) of the NV centers to split based upon an external magnetic field projected along the NV axis, resulting in two spin resonance frequencies. The distance between the two spin resonance frequencies is a measure of the strength of the external magnetic field. A photo detector can measure the fluorescence (red light) emitted by the optically excited NV centers.

Magneto-optical defect center materials are those that can modify an optical wavelength of light directed at the defect center based on a magnetic field in which the magneto-defect center material is exposed. In some examples, the magneto-optical defect center material may utilize nitrogen vacancy centers. Nitrogen-vacancy (NV) centers are defects in a diamond's crystal structure. Synthetic diamonds can be created that have these NV centers. NV centers generate red light when excited by a light source, such as a green light source, and microwave radiation. When an excited NV center diamond is exposed to an external magnetic field, the frequency of the microwave radiation at which the diamond generates red light and the intensity of the generated red light change. By measuring this change and comparing the change to the microwave frequency that the diamond generates red light at when not in the presence of the external magnetic field, the external magnetic field strength can be determined. Accordingly, NV centers can be used as part of a magnetic field sensor.

In some examples, microwave RF excitation may be used in a DNV sensor. The more uniform the microwave signal is across the NV centers in the diamond, the better and more accurate a NV sensor can perform. Uniformity, however, can be difficult to achieve. Also, the larger the bandwidth of the element, the better the NV sensor can perform. Large bandwidth, such as octave bandwidth, however, can be difficult to achieve. Various NV sensors respond to a microwave frequency that is not easily generated by RF antenna elements that are comparable to the small size of the NV sensor. In addition, RF elements reduce the amount of light within the sensor that is blocked by the RF elements. When a single RF element is used, the RF element is offset from the NV diamond when the RF element maximizes the faces and edges of the diamond that light can enter or leave. Moving the RF element away from the NV diamond, however, impacts the uniformity of strength of the RF that is applied to the NV diamond.

Some of the examples realize that the DNV magnetic sensors with dual RF elements provide a number of advantages. As described in greater detail below, using a two RF element arrangement in a DNV sensor can allow greater access to the edges and faces of the diamond for light input and egress, while still exciting the NV centers with a uniform RF field. In some examples, each of the two microwave RF elements is contained on a circuit board. The RF elements can include multiple stacked spiral antenna coils. These stacked coils can occupy a small footprint and can provide the microwave RF field such that the RF field is uniform over the NV diamond.

In addition, all edges and faces of the diamond can be used for light input and egress. The more light captured by photo-sensing elements of a DNV senor can result in an increased efficiency of the sensor. Various examples use the dual RF elements to increase the amount of light collected by the DNV sensor. The dual RF elements can be fed by a single RF feed or by two separate RF feeds. If there are two RF feeds, the feeds can be individual controlled creating a mini-phased array antenna effect, which can enhance the operation of the DNV sensor.

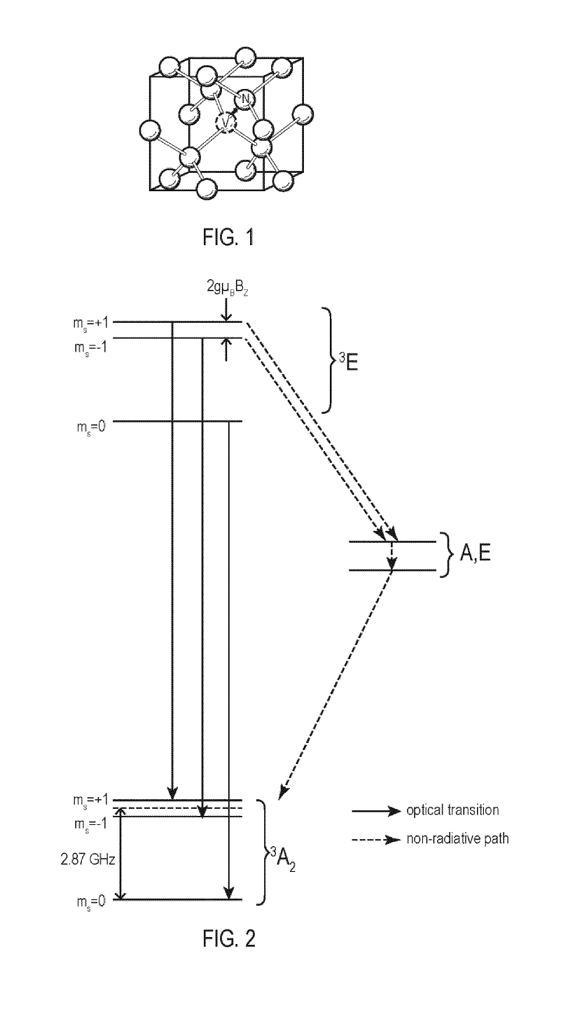

The NV center in a diamond may comprise a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. The neutral charge state uses the nomenclature NV⁰, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing an external magnetic field with a component along the NV axis lifts the degeneracy of the mₛ=±1 energy levels, splitting the energy levels mₛ=±1 by an amount 2 gμ_{B}B_{z}, where g is the g-factor, μ_{B} is the Bohr magneton, and B_{z} is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

The NV Center, or Magneto-Optical Defect Center, Magnetic Sensor System

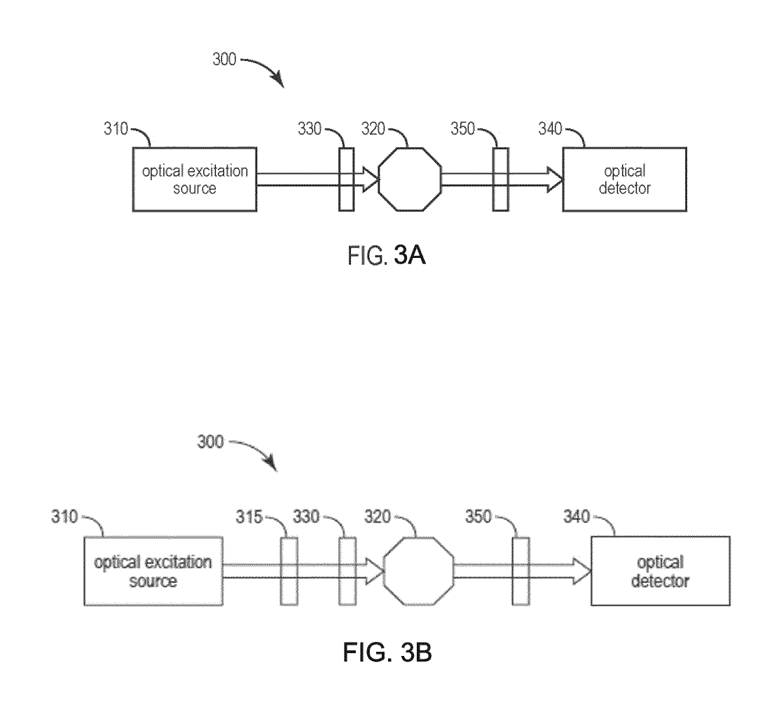

FIG. 3A is a schematic diagram illustrating a NV center magnetic sensor system 300A that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300A includes an optical excitation source 310, which directs optical excitation to an NV diamond material 320 with NV centers. The system further includes an RF excitation source 330, which provides RF radiation to the NV diamond material 320. Light from the NV diamond may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the NV diamond material 320 is directed through the optical filter 350 to filter out light in the excitation band (in the green, for example), and to pass light in the red fluorescence band, which in turn is detected by the optical detector 340. The optical excitation source 310, in addition to exciting fluorescence in the NV diamond material 320, also serves to reset the population of the mₛ=0 spin state of the ground state ³A₂ to a maximum polarization, or other desired polarization.

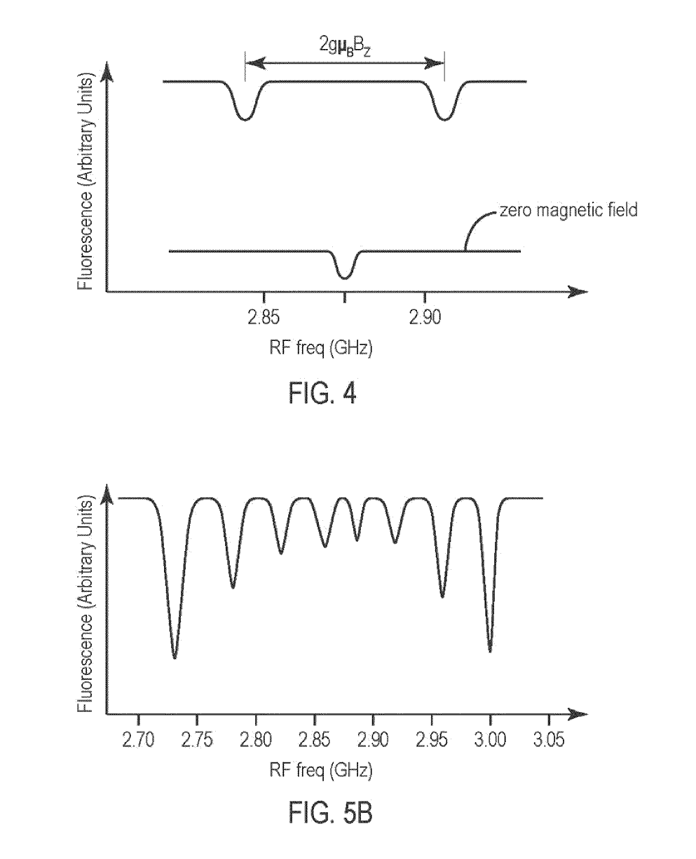

For continuous wave excitation, the optical excitation source 310 continuously pumps the NV centers, and the RF excitation source 330 sweeps across a frequency range that includes the zero splitting (when the mₛ=±1 spin states have the same energy) photon energy of approximately 2.87 GHz. The fluorescence for an RF sweep corresponding to a NV diamond material 320 with NV centers aligned along a single direction is shown in FIG. 4 for different magnetic field components B_{z} along the NV axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence, and spin echo pulse sequence.

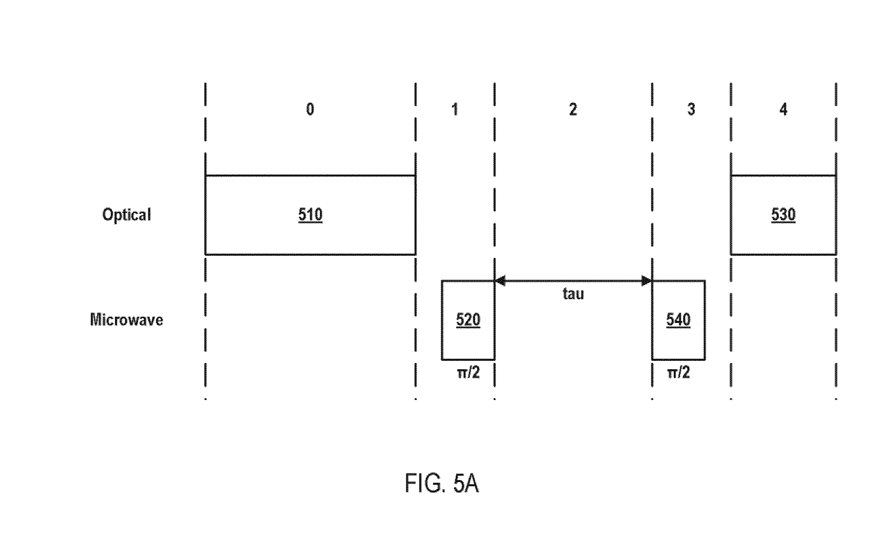

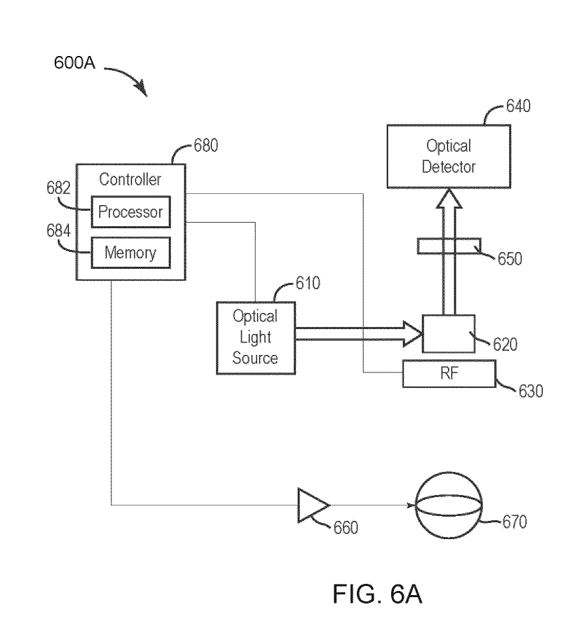

The Ramsey pulse sequence is a pulsed RF-pulsed laser scheme that measures the free precession of the magnetic moment in the NV diamond material 320 with NV centers, and is a technique that quantum mechanically prepares and samples the electron spin state. FIG. 5A is a schematic diagram illustrating the Ramsey pulse sequence. As shown in FIG. 5A, a Ramsey pulse sequence includes optical excitation pulses and RF excitation pulses over a five-step period. In a first step, during a period 0, a first optical excitation pulse 510 is applied to the system to optically pump electrons into the ground state (i.e., mₛ=0 spin state). This is followed by a first RF excitation pulse 520 (in the form of, for example, a microwave (MW) π/2 pulse) during a period 1. The first RF excitation pulse 520 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 540 (in the form of, for example, a MW π/2 pulse) is applied during a period 3 to project the system back to the mₛ=0 and mₛ=+1 basis. Finally, during a period 4, a second optical pulse 530 is applied to optically sample the system and a measurement basis is obtained by detecting the fluorescence intensity of the system. The RF excitation pulses applied are provided at a given RF frequency, which correspond to a given NV center orientation.

In general, the NV diamond material 320 will have NV centers aligned along directions of four different orientation classes. FIG. 5B illustrates fluorescence as a function of RF frequency for the case where the NV diamond material 320 has NV centers aligned along directions of four different orientation classes. In this case, the component B_{z} along each of the different orientations may be determined. These results, along with the known orientation of crystallographic planes of a diamond lattice, allow not only the magnitude of the external magnetic field to be determined, but also the direction of the magnetic field.

FIG. 3B is a schematic diagram illustrating a NV center magnetic sensor system 300B with a waveplate 315. The NV center magnetic sensor system 300B uses fluorescence intensity to distinguish the mₛ=±1 states, and to measure the magnetic field based on the energy difference between the mₛ=+1 state and the mₛ=−1 state. The system 300B includes an optical excitation source 310, which directs optical excitation through a waveplate 315 to a NV diamond material 320 with defect centers (e.g., NV diamond material). The system further includes an RF excitation source 330, which provides RF radiation to the NV diamond material 320. Light from the NV diamond may be directed through an optical filter 350 to an optical detector 340.

In some examples, the RF excitation source 330 may be a microwave coil. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state, or between the mₛ=0 spin state and the mₛ=+1 spin state, there is a decrease in the fluorescence intensity.

In some examples, the optical excitation source 310 may be a laser or a light emitting diode which emits light in the green. In some examples, the optical excitation source 310 induces fluorescence in the red, which corresponds to an electronic transition from the excited state to the ground state. In some examples, the light from the optical excitation source 310 may be directed through a waveplate 315. In some examples, light from the NV diamond material 320 may be directed through the optical filter 350 to filter out light in the excitation band (in the green, for example), and to pass light in the red fluorescence band, which in turn may be detected by the optical detector 340. The optical excitation source 310, in addition to exciting fluorescence in the NV diamond material 320, also serves to reset the population of the mₛ=0 spin state of the ground state ³A₂ to a maximum polarization, or other desired polarization.

In some examples, the light may be directed through a waveplate 315. In some examples, the waveplate 315 may be in a shape analogous to a cylinder solid with an axis, height, and a base. In some examples, the performance of the system may be affected by the polarization of the light (e.g., light from a laser) as it may be lined up with a crystal structure of the NV diamond material 320. In some examples, a waveplate 315 may be mounted to allow for rotation of the waveplate 315 with the ability to stop and/or lock the waveplate 315 in to position at a specific rotation orientation. This allows the tuning of the polarization relative to the NV diamond material 320. Affecting the polarization of the system allows for the affecting the responsive Lorentzian curves. In some examples where the waveplate 315 is a half-wave plate such that, when a laser polarization may be lined up with the orientation of a given lattice of the NV diamond material 320, the contrast of the dimming Lorentzian, the portion of the light sensitive to magnetic fields, is deepest and narrowest so that the slope of each side of the Lorentzian is steepest. In some examples where the waveplate 315 is a half-wave plate, a laser polarization lined up with the orientation of a given lattice of the NV diamond material 320 allows extraction of maximum sensitivity for the measurement of an external magnetic field component aligned with the given lattice. In some examples, four positions of the waveplate 315 are determined to maximize the sensitivity to different lattices of the NV diamond material 320. In some examples, a position of the waveplate 315 may be determined to get similar sensitivities or contrasts to the four Lorentzians corresponding to lattices of the NV diamond material 320.

In some examples where the waveplate 315 may be a half-wave plate, a position of the waveplate 315 may be determined as an initial calibration for a light directed through a waveplate 315. In some examples, the performance of the system may be affected by the polarization of the light (e.g., light from a laser) as it may be lined up with a crystal structure of the NV diamond material 320. In some examples, a waveplate 315 may be mounted to allow for rotation of the waveplate 315 with the ability to stop and/or lock the half-wave after an initial calibration determines the eight Lorentzians associated with a given lattice with each pair of Lorentzians associated with a given lattice plane symmetric around the carrier frequency. In some examples, the initial calibration may be set to allow for high contrast with steep Lorentzians for a particular lattice plane. In some examples, the initial calibration may be set to create similar contrast and steepness of the Lorentzians for each of the four lattice planes. The structural details of the waveplate 315 will be discussed in further detail below

While FIGS. 3A-3B illustrate an NV center magnetic sensor system 300A, 300B with NV diamond material 320 with a plurality of NV centers, in general, the magnetic sensor system may instead employ a different magneto-optical defect center material, with a plurality of magneto-optical defect centers. The electronic spin state energies of the magneto-optical defect centers shift with magnetic field, and the optical response, such as fluorescence, for the different spin states may be not the same for all of the different spin states. In this way, the magnetic field may be determined based on optical excitation, and possibly RF excitation, in a corresponding way to that described above with NV diamond material. Magneto-optical defect center materials include but are not limited to diamonds, Silicon Carbide (SiC) and other materials with nitrogen, boron, or other chemical defect centers. Our references to diamond-nitrogen vacancies and diamonds are applicable to magneto-optical defect center materials and variations thereof.

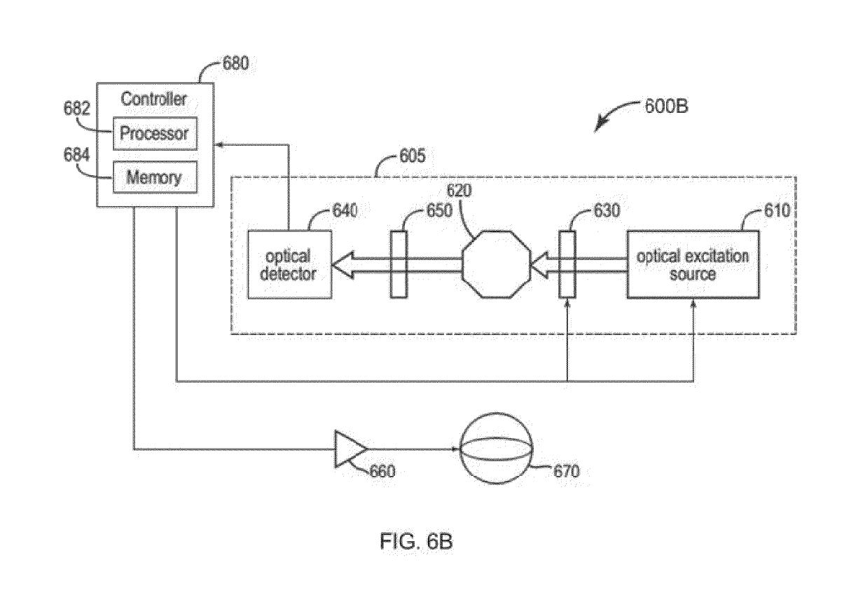

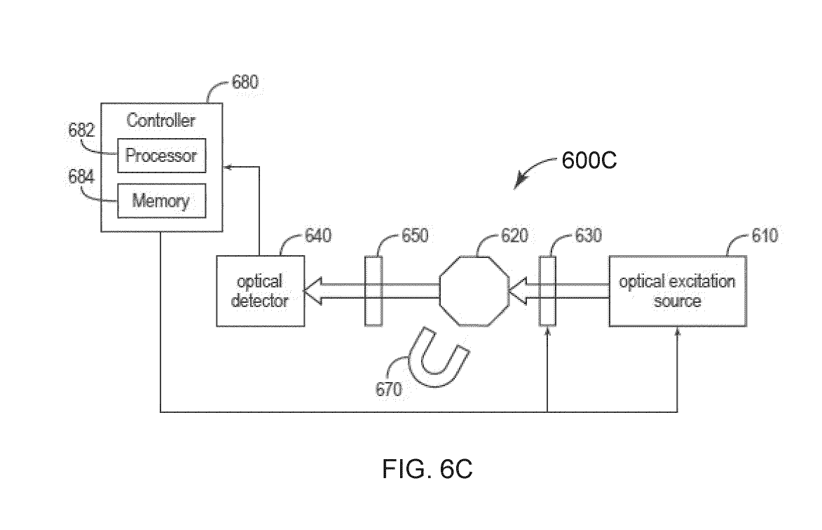

FIG. 6A illustrates a magnetic field detection system 600A according to some examples. The system 600A includes an optical excitation source 610 (i.e., the optical excitation source 310 of FIGS. 3A and 3B), which directs optical light to an NV diamond material 620 (i.e., the NV diamond material 320 of FIGS. 3A and 3B) with NV centers, or another magneto-optical defect center material with magneto-optical defect centers. An RF excitation source 630 (i.e., the RF excitation source 330 of FIGS. 3A and 3B) provides RF radiation to the NV diamond material 620. The system 600A may include a magnetic field generator 670 which generates a magnetic field, which may be detected at the NV diamond material 620, or the magnetic field generator 670 may be external to the system 600A. The magnetic field generator 670 may provide a biasing magnetic field.

FIG. 6B is another schematic diagram of a magnetic field detection system 600B according to some examples. The system 600B includes an optical excitation source 610 (i.e., the optical excitation source 310 of FIGS. 3A and 3B), which directs optical excitation to a NV diamond material 620 (i.e., the NV diamond material 320 of FIGS. 3A and 3B) with defect centers. An RF excitation source 630 (i.e., the RF excitation source 330 of FIGS. 3A and 3B) provides RF radiation to the NV diamond material 620. A magnetic field generator 670 generates a magnetic field, which may be detected at the NV diamond material 620.

Referring to both FIGS. 6A and 6B, the system 600A, 600B further includes a controller 680 arranged to receive a light detection signal from the optical detector 640 (i.e., the optical detector 340 of FIGS. 3A and 3B) and to control the optical excitation source 610, the RF excitation source 630, and the magnetic field generator 670. The controller 680 may be a single controller, or multiple controllers. For a controller 680 including multiple controllers, each of the controllers may perform different functions, such as controlling different components of the system 600A, 600B. The magnetic field generator 670 may be controlled by the controller 680 via an amplifier 660, for example.

The RF excitation source 630 may be controlled to emit RF radiation with a photon energy resonant with the transition energy between the ground mₛ=0 spin state and the mₛ=±1 spin states as discussed above with respect to FIGS. 3A or 3B, or to emit RF radiation at other no resonant photon energies.

The controller 680 may be arranged to receive a light detection signal from the optical detector 640 and to control the optical excitation source 610, the RF excitation source 630, and the magnetic field generator 670. The controller 680 may include a processor 682 and a memory 684, in order to control the operation of the optical excitation source 610, the RF excitation source 630, and the magnetic field generator 670. The memory 684, which may include a no transitory computer readable medium, may store instructions to allow the operation of the optical excitation source 610, the RF excitation source 630, and the magnetic field generator 670 to be controlled. That is, the controller 680 may be programmed to provide control.

The magnetic field generator 670 may generate magnetic fields with orthogonal polarizations, for example. In this regard, the magnetic field generator 670 may include two or more magnetic field generators, such as two or more Helmholtz coils. The two or more magnetic field generators may be configured to provide a magnetic field having a predetermined direction, each of which provide a relatively uniform magnetic field at the NV diamond material 620. The predetermined directions may be orthogonal to one another. In addition, the two or more magnetic field generators of the magnetic field generator 670 may be disposed at the same position, or may be separated from each other. In the case that the two or more magnetic field generators are separated from each other, the two or more magnetic field generators may be arranged in an array, such as a one-dimensional or two-dimensional array, for example.

The system 600A may be arranged to include one or more optical detection systems 605, where each of the optical detection systems 605 includes the optical detector 640, optical excitation source 610, and NV diamond material 620. Similarly, the system 600B also includes the optical detector 640, optical excitation source 610, and NV diamond material 620. The magnetic field generator 670 may have a relatively high power as compared to the optical detection systems 605. In this way, the optical systems 605 may be deployed in an environment that requires a relatively lower power for the optical systems 605, while the magnetic field generator 670 may be deployed in an environment that has a relatively high power available for the magnetic field generator 670 so as to apply a relatively strong magnetic field.

The RF excitation source 630 may be a microwave coil, for example behind the light of the optical excitation source 610. The RF excitation source 630 may be controlled to emit RF radiation with a photon energy resonant with the transition energy between the ground mₛ=0 spin state and the mₛ=±1 spin states as discussed above with respect to FIGS. 3A and 3B.

The optical excitation source 610 may be a laser or a light emitting diode, for example, which emits light in the green, for example. The optical excitation source 610 induces fluorescence in the red from the NV diamond material 620, where the fluorescence corresponds to an electronic transition from the excited state to the ground state. Light from the NV diamond material 620 may be directed through the optical filter 650 to filter out light in the excitation band (in the green, for example), and to pass light in the red fluorescence band, which in turn may be detected by the optical detector 640. The optical excitation source 610, in addition to exciting fluorescence in the NV diamond material 620, also serves to reset the population of the mₛ=0 spin state of the ground state ³A₂ to a maximum polarization, or other desired polarization.

The controller 680 may be arranged to receive a light detection signal from the optical detector 640 and to control the optical excitation source 610, the RF excitation source 630, and a second magnetic field generator (not illustrated). The controller may include a processor 682 and a memory 684, in order to control the operation of the optical excitation source 610, the RF excitation source 630, and the second magnetic field generator. The memory 684, which may include a no transitory computer readable medium, may store instructions to allow the operation of the optical excitation source 610, the RF excitation source 630, and the second magnetic field generator to be controlled. That is, the controller 680 may be programmed to provide control.

FIG. 6C is a schematic of an NV center magnetic sensor system 600C, according to an embodiment. The sensor system 600C includes an optical excitation source 610, which directs optical excitation to an NV diamond material 620 with NV centers, or another magneto-optical defect center material with magneto-optical defect centers. An RF excitation source 630 provides RF radiation to the NV diamond material 620. The NV center magnetic sensor system 600C may include a bias magnet (bias magnetic field generator 670) applying a bias magnetic field to the NV diamond material 620. Unlike FIGS. 6A and 6B, the sensor system 600C of FIG. 6C does not include the amplifier 660. However, in some examples of the NV center magnetic sensor system 600C, an amplifier 660 may be utilized. Light from the NV diamond material 620 may be directed through an optical filter 650 and optionally, an electromagnetic interference (EMI) filter (not illustrated), which suppresses conducted interference, to an optical detector 640. The sensor system 600C further includes a controller 680 arranged to receive a light detection signal from the optical detector 640 and to control the optical excitation source 610 and the RF excitation source 630.

The optical excitation source 610 may be a laser or a light emitting diode, for example, which emits light in the green, for example. The optical excitation source 610 induces fluorescence in the red, which corresponds to an electronic transition from the excited state to the ground state. Light from the NV diamond material 620 may be directed through the optical filter 650 to filter out light in the excitation band (in the green for example), and to pass light in the red fluorescence band, which in turn may be detected by the optical detector 640. In examples including the EMI filter, the EMI filter may be arranged between the optical filter 650 and the optical detector 640 and suppresses conducted interference. The optical excitation source 610, in addition to exciting fluorescence in the NV diamond material 620, also serves to reset the population of the mₛ=0 spin state of the ground state ³A₂ to a maximum polarization, or other desired polarization.

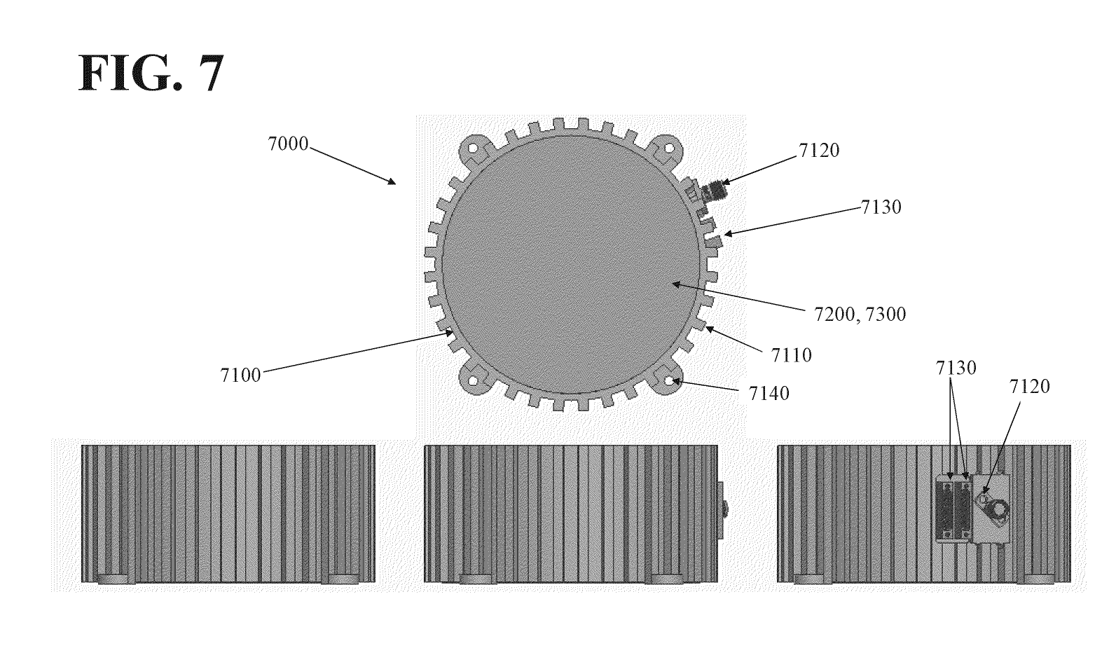

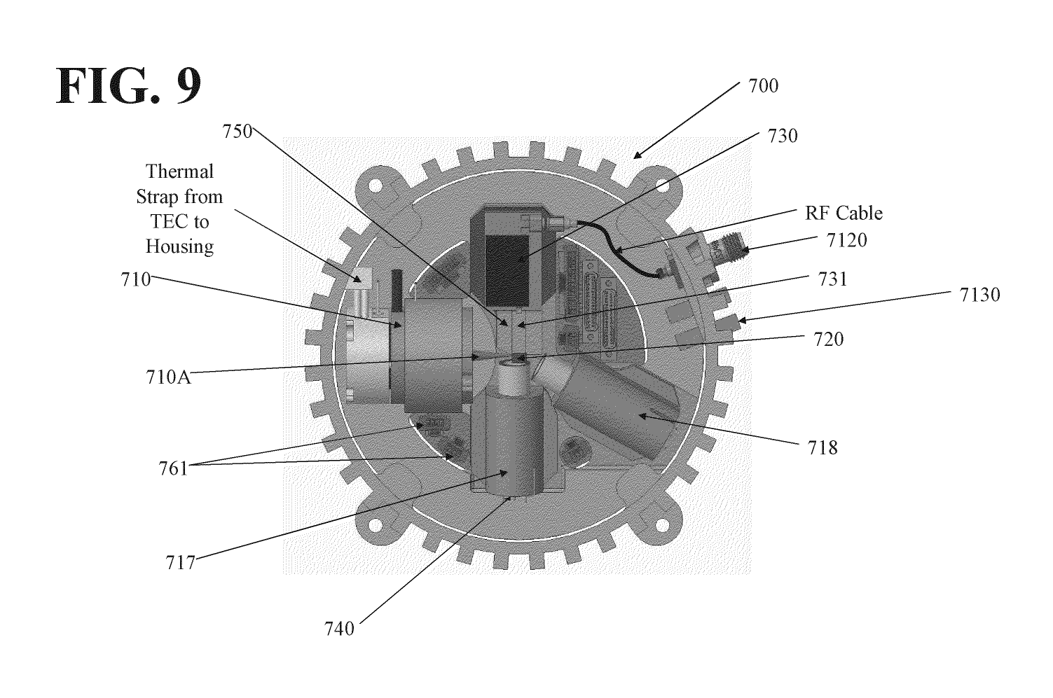

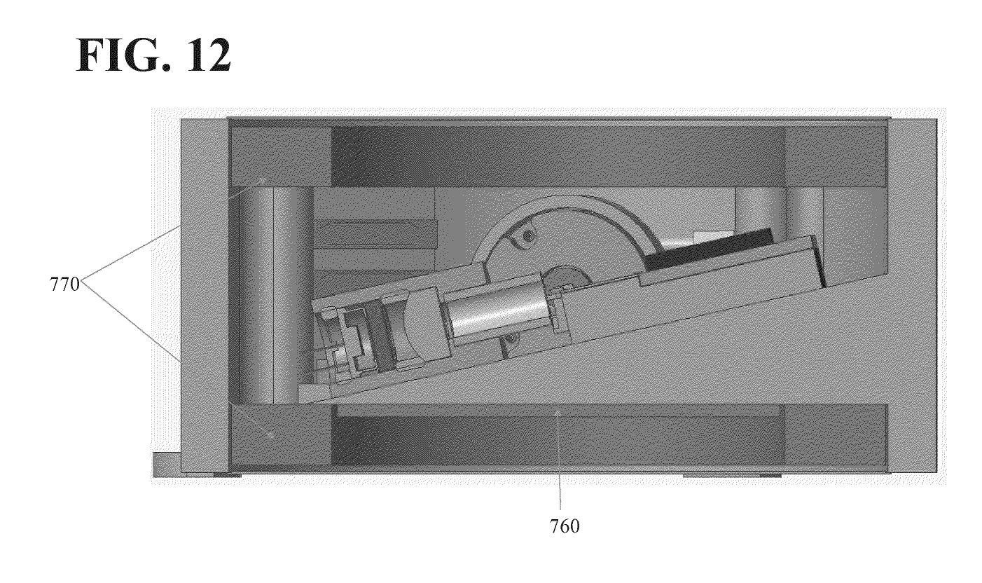

Referring to FIG. 9, a magnetometer 700 may include a housing 7000 (FIG. 7), a magneto-optical defect center material 720 comprising at least one magneto-optical defect center that emits an optical signal when excited by an excitation light 710A, a radio frequency (RF) exciter system configured to provide RF excitation to the magneto-optical defect center material 720, an optical light system 710 configured to direct the excitation light 710A to a target such as a magneto-optical defect center material 720 (e.g., a nitrogen vacancy (NV) diamond material with one or more NV centers, or another magneto-optical defect center material with one or more magneto-optical defect centers), a magnetic field generator 770 (FIG. 12), and an optical detector 740 configured to receive the optical signal emitted by the magneto-optical defect center material based on the excitation light and the RF excitation.

Housing

Referring to FIG. 7, the individual components of the magnetometer 700 (e.g., the magneto-optical defect center material 720, the optical light system 710, the magnetic field generator 770, the optical detector 740, etc.) may be provided in a housing 7000 that includes a shell portion 7100, a first lid 7200 fixed to an upper surface (i.e., a top surface) of the shell portion 7100, and a second lid 7300 fixed to a lower surface (i.e., a bottom surface) of the shell portion 7100. Although in the example illustrated in FIG. 7, the housing 7000 is cylindrical, the concepts disclosed herein are not limited in this regard. In other examples, the housing 7000 may be any other shape, for example, rectangular.

In some examples, the first lid 7200 and the second lid 7300 are permanently and non-reversibly fixed to the shell portion 7100, for example, by welding (e.g., laser welded) to hermetically seal the housing 7000. In other examples, the first lid 7200 and the second lid 7300 are reversibly fixed to the shell portion 7100, for example, via any known fastener such as a screw. In examples in which the first lid 7200 and the second lid 7300 are screwed to the shell portion 7100, an O-ring (e.g., a metallic O-ring) or other gasket may be used to seal between a respective lid 7200, 7300 and the shell portion 7100. The seal may be a hermetic seal. In other examples, the first lid 7200 and the second lid 7300 may be fixed to the shell portion 7100 by an epoxy or adhesive. In some examples, a metalized optical window may be used.

In some examples, the housing 7000 is hermetically sealed. Thus, purge gas systems and gaskets may be excluded from the magnetometer 700, in particular, from the housing 7000.

In some examples, the shell portion 7100 may be made of the same material as the first lid 7200 and the second lid 7300. In other examples, the shell portion 7100 may be made from a different material than the first lid 7200 and the second lid 7300. The material from which the shell portion 7100, the first lid 7200 and the second lid 7300 are made may depend on a specific application of the magnetometer 700 and the frequency to be measured by the magnetometer 700. The material from which the shell portion 7100, the first lid 7200 and the second lid 7300 may be a semi-conductive material or conductive material. For example, the shell portion 7100, the first lid 7200 or the second lid 7300 may be made from titanium, aluminum, copper and alloys thereof; stainless steel; or diamond (this list is non-exhaustive). In some examples, the shell portion 7100, the first lid 7200 or the second lid 7300 may be made from aluminum pyrolytic graphite or aluminum silicon carbide. In further examples, the shell portion 7100, the first lid 7200 or the second lid 7300 may be made from ceramic materials (e.g., high temperature cofired ceramics, low temperature cofired ceramics, alumina ceramics, etc.).

An outer perimeter or circumference of the housing 7000 may include one or more fins 7110 that increase a surface area of the housing and facilitate natural convection cooling. In some examples, a plurality of fins 7110 are provided with equal spacing between adjacent fins 7110. The outer perimeter or circumference of the housing 7000 may further include at least one cable connector 7120. For the example, the cable connector 7120 may be an RF input configured to receive a coaxial cable. The outer perimeter or circumference of the housing 7000 may further include at least one pin connector 7130. In some examples, the outer perimeter or circumference of the housing 7000 includes two pin connectors 7130, for example, the first pin connector 7130 configured to receive a power cable and the second pin connector configured to receive a signal cable. One of ordinary skill in the art would understand that one end of the cable connector 7120 and one end of the pin connector 7130 may protrude outwards from the shell portion 7100 (i.e., towards an exterior of the housing 7000), while the other end of the cable connector 7120 and the other end of the pin connector 7130 may protrude inwards from the shell portion 7100 (i.e., towards an interior of the housing 7000). Each of the cable connector 7120 and the pin connector 7130 is hermetically installed. The outer perimeter or circumference of the housing 7000 may further include one or more mounting tabs 7140 to facilitate mounting of the magnetometer 700 to a desired surface. Each mounting tab 7140 includes an aperture configured to receive a fastener, for example, a screw or a bolt.

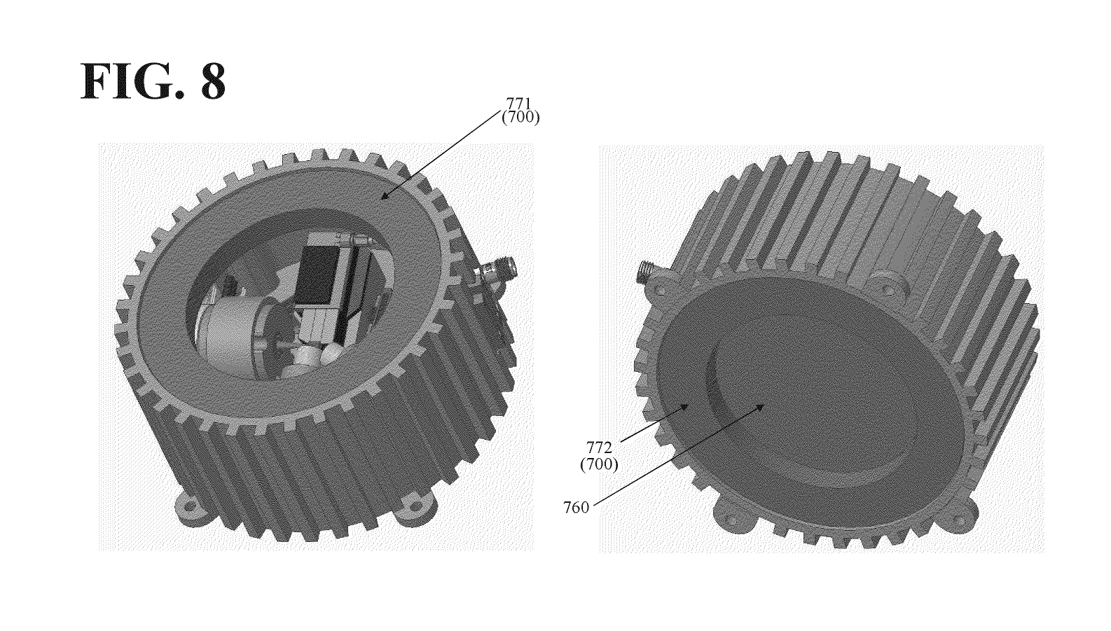

Referring to FIG. 8, the individual components of the magnetometer 700 (e.g., the magneto-optical defect center material 720, the optical light system 710, the magnetic field generator 770, the optical detector 740, etc.) are mounted to a circuit board 760 provided within the housing 7000. The circuit board 760 may include one or more pin connectors 761 (FIG. 9) configured to receive power or signal cables.

RF Exciter System and Optical System

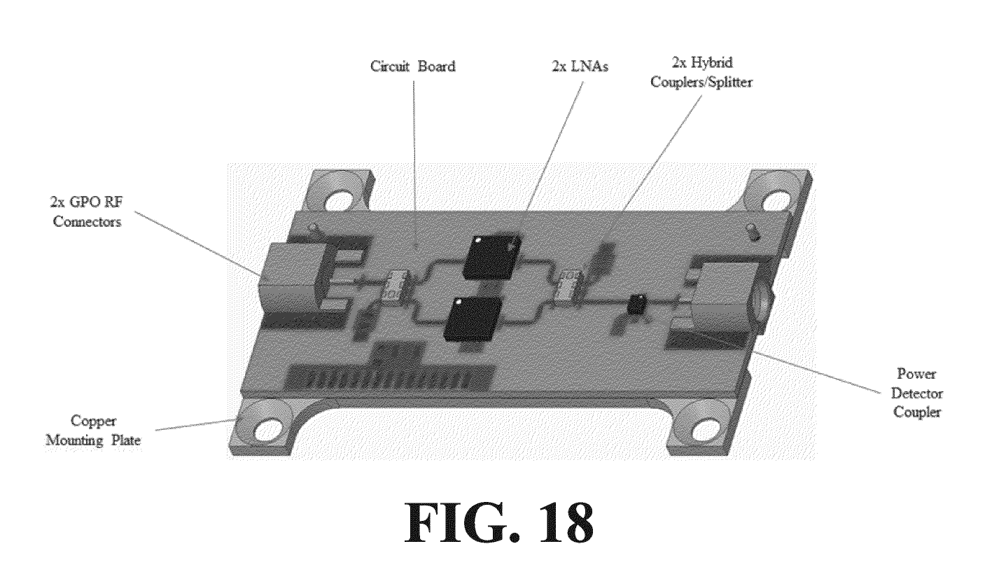

The RF exciter system may include an RF amplifier assembly 730 (FIG. 9), which includes RF circuitry that amplifies the signal from the RF source to a desired power level needed in the RF excitation element 731. As seen in FIG. 18, the RF amplifier assembly 730 may include multiple individually packaged chips attached to a printed circuit board. In the examples of FIG. 18, the printed circuit board is not one of the circuit boards that makes up the RF excitation element 731. Alternatively, the RF amplifier assembly 730 may include multiple bare die chips in a common single package. The single package may be attached to a simplified version of the printed circuit board of FIG. 18 or to one of the circuit boards that makes up the RF excitation element 731. It is possible to save space/reduce the size of the magnetometer by using the bare die parts and placing them into a single plastic covered package versus using individually plastic packaged chips and individually attaching them on a printed circuit board. Pre-packaged chips are about 30%-80% larger in area than that same chip in bare die form. As used herein “bare die” may refer to a chip (e.g., a GaN, GaAs, Si, etc.) that has been singulated from the wafer it was constructed on, but has not undergone any other processing/packaging.

Referring to FIG. 9, in the magnetometer 700, light from the magneto-optical defect center material 720 may be directed through an optical filter to filter out light in the excitation band (in the green, for example), and to pass light in the red fluorescence band through a light pipe, which in turn may be detected by the optical detector 740. A red collection 717 and a green collection 718 may be provided around a periphery of a base 750 to which the magneto-optical defect center material 720 is mounted. The red collection 717 may be a system of parts that includes, for example, a photo diode, a light pipe, and filters that measure the red light emitted from the magneto-optical defect center material 720. The red collection 717 provides the main signal of interest, used to measure external magnetic fields. The green collection 718 may be a system of parts that includes, for example, a photo diode, a light pipe, and filters that measure the green light from the excitation light that passes through the magneto-optical defect center material 720. The green collection 718 may be used in tandem with the red collection 717 to remove common mode noise in the detection signal, and therefore, increase device sensitivity. A beam trap configured to capture any portion of the excitation light (e.g., a green light portion) that may be not absorbed by the magneto-optical defect center material 720 may be provided to ensure that that the excitation light does not bounce around and add noise to the measurement. This noise could result from the excitation light bouncing off other components of the magnetometer 700 and hitting the magneto-optical defect center material 720 at a later time, where the excitation light would be absorbed and contaminate the signal. The excitation light that is not absorbed by the magneto-optical defect center material 720 might also be captured on the green or red collection photodiodes, directly adding noise to those signals.

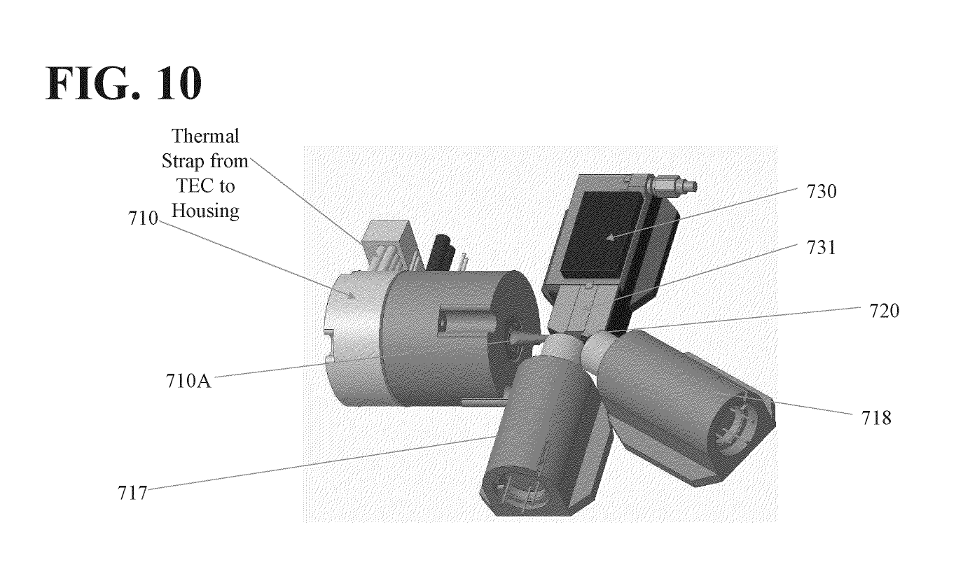

In alternative examples, additional, fewer, and/or different elements may be used. For example, although the optical light system 710 of FIGS. 9-11 illustrate one light source, in other examples, the optical light system 710 may include any suitable number of light sources, such as two, three, four, etc. light sources. An orientation of the magneto-optical defect center material 720 may be changed.

A light pipe with a lens at the end of the light pipe may provide a collection system that efficiently starts and ends the process of directing and focusing the light to the photo diode. The light pipe efficiently collects a large amount of light from the light source and then directs that light to a lens or system of lenses which then efficiently focus the light onto the collection surface of the photo diode such that the maximum amount of light is collected and measured. Since the sensitivity of an optical defect based magnetometer is directly related to the efficiency of the light collection, the combination of a light pipe with a lens or lenses results in a direct sensitivity improvement for the magnetometer system.

Magneto-optical defect center materials such as diamonds with nitrogen vacancy (NV) centers can be used to detect magnetic fields. Green light which enters a diamond structure with defect centers interacts with defect centers, and red light is emitted from the diamond. The amount of red light emitted can be used to determine the strength of the magnetic field. The efficiency and accuracy of sensors using magneto-optical defect center materials such as diamonds with NV centers (DNV sensors) is increased by transferring as much light as possible from the defect centers to the photo sensor that measures the amount of red light. Magneto-optical defect center materials include but are not be limited to diamonds, Silicon Carbide (SiC) and other materials with nitrogen, boron, or other chemical defect centers.

In some examples, a coated, hollow light pipe is used to improve the optics and specifically the light collection efficiency in an optical defect center based magnetometer where the light collection optics directly relate to the performance of the magnetometer. While solid glass or other manufactured solid optical material light pipes may be used, such solid light pipes may suffer from efficiency issues. Solid light pipes have at least the efficiency issues of entrance loss, where some of the light entering the light pipe is reflected, absorption, where the solid material attenuates some of the light through the length of the pipe through absorption, escape of light through the sides of the light pipe, where light hitting an edge of the light pipe at an angle beyond the angle for total internal reflection escapes through the side of the light pipe, and exit loss, where some of the light exiting the solid material light pipe is reflected back into it.

A tubular, hollow light pipe has the benefits of no entrance loss or exit loss because the tube is not a solid material but rather hollow in the middle where the light may be traveling. There may be nearly no attenuation loss because the hollow center of the tube where the light travels is full of air, which over the length of most light pipes has no measurable attenuation of the light. In some embodiments, there are no or reduced escape issues from the total internal reflection because the reflective coating on the inside of the hollow portion of the light pipe directs the light from the entrance side to the exit side. If a reflective coating is used, there may be some amount of light that, but still much less absorption than through a solid material light pipe.

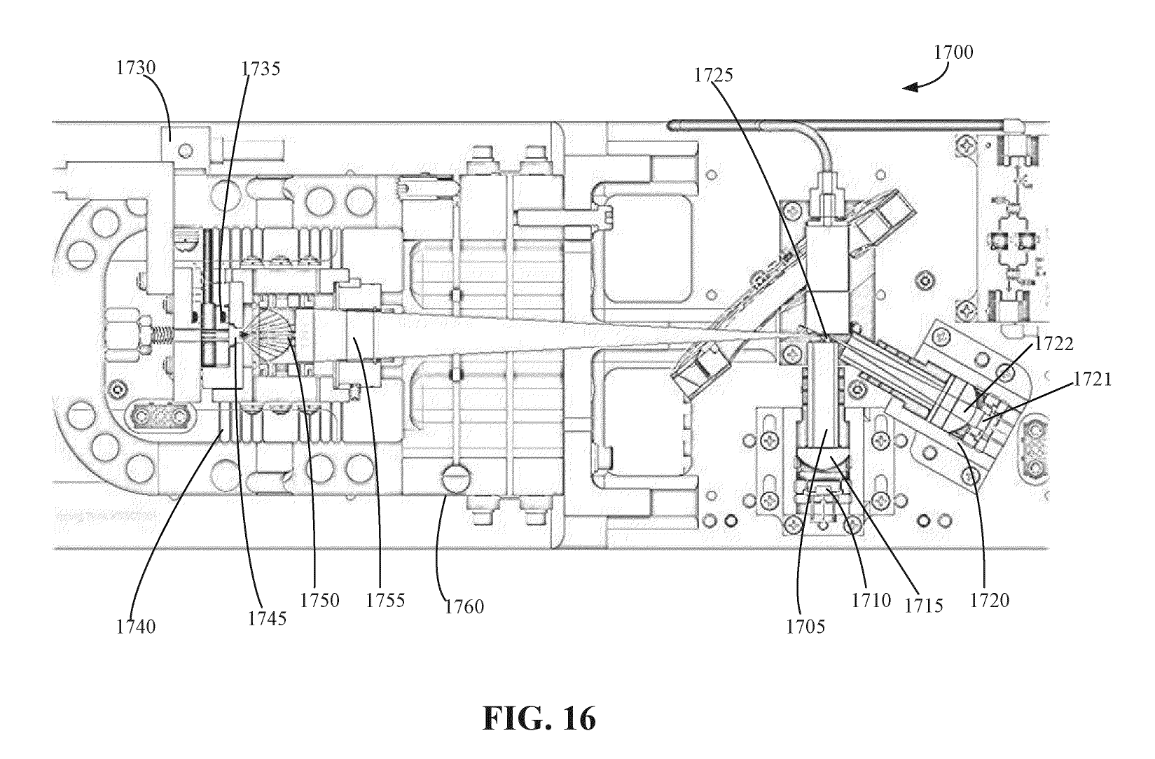

FIG. 16 illustrates an optical excitation assembly 1700 as a cross-section including light pipes in accordance with some embodiments. The optical excitation assembly 1700 may include, in brief, a first light pipe 1705, a photo diode 1710 (e.g., a photo diode for detecting red light), a lens assembly with red filter 1715, a second light pipe 1720 (with similar corresponding assembly to the first light pipe 1705 but for detecting green light), a photo diode 1721 (e.g., a photo diode for detecting green light), a lens assembly with green filter 1722, a magneto-optical defect center material 1725 with defect centers, an accelerometer 1730, one or more thermistors 1735, laser position adjustment flexure rib array 1740, an optical excitation module 1745, an optical excitation focusing lens cell 1750, a waveplate for laser polarization control 1755, and a laser angle adjustment flexure rib 1760.

The optical excitation assembly 1700 may comprise a first light pipe 1705. In some embodiments, the first light pipe 1705 may be configured to operably connect to an assembly for detecting red light (e.g., using a photo diode 1710 configured to detect red light). The first light pipe 1705 may have any appropriate geometry. In some embodiments, the first light pipe 1705 may be cylindrical and hollow. The hollow inside surface may be coated with a reflective surface. In some embodiments, the first light pipe 1705 comprises a copper structure, silver inner reflective surface, and gold outer surface. A light pipe with such a structure may have approximately 95% reflection at a wavelength of light of 515 nm. In some embodiments, the reflection increases as the wavelength increases. In some embodiments, the first light pipe 1705 may be configured to be mountable as outer points of the light pipe can be contacted without increasing emission loss from the light pipe. In some embodiments, the first light pipe 1705 may have a circular cross-section, square cross-section, rectangular cross-section, hexagonal cross-section, or octagonal cross-section. In some embodiments, the light pipe may be a tubular piece of glass or metal (e.g., copper) that may be hollow on the inside and that has an inside surface coated with a reflective coating that directs light from the entrance side to the exit side such that the first light pipe 1705 functions as a light pipe. The first light pipe 1705 may be formed from any appropriate material (e.g., copper structure). In some embodiments, the optical excitation assembly 1700 comprises a second light pipe 1720. In some embodiments, the second light pipe 1720 comprises a second light pipe configured to operably connect to the assembly for detecting green light similar to the above configuration for the first light pipe 1705.

The light pipe can be selected to have an appropriate aperture size. The aperture of the light pipe can be selected to be matched to or smaller than the optical detector. This size relationship allows the optical detector to capture the highest possible percentage of the light emitted by the light pipe. The aperture of the light pipe can be also selected to be larger than the surface of the diamond material to which it may be coupled. This size relationship allows the light pipe to capture the highest possible percentage of light emitted by the magneto-optical defect center material. In some embodiments, the light pipe may have an aperture of about 4 mm. In some other embodiments, the light pipe may have an aperture of about 2 mm. In some embodiments, the light pipe may have an aperture of 4 mm, and the magneto-optical defect material may have a coupled surface with a height of 0.6 mm and a length of 2 mm, or less. The light pipe may have any appropriate length, such as about 25 mm. The light pipe can be positioned such that the end surface of the light pipe adjacent the magneto-optical material may be parallel, or substantially parallel, to the associated surface of the magneto-optical material. This arrangement allows the light pipe to capture an increased amount of the light emitted by the magneto-optical defect center material as possible. The alignment of the surfaces of the light pipe and the magneto-optical defect center material ensures that a maximum amount of the light emitted by the magneto-optical defect center material will intersect the end surface of the light pipe, thereby being captured by the light pipe.

The optical excitation assembly 1700 comprises a photo diode 1710. In some embodiments, the photo diode 1710 may be configured to collect light (e.g., red or green light collection).

The optical excitation assembly 1700 comprises a lens assembly with red filter 1715. In some examples, light from the magneto-optical defect center material 1725 may be directed through the lens assembly with red filter 1715 to filter out light in the excitation band (in the green, for example), and to pass light in the red fluorescence band. The lens assembly with red filter 1715 may be any appropriate optical filter capable of transmitting red light and reflecting other light, such as green light. In some embodiments, the red filter may be a coating applied to an end surface of the lens assembly. The coating may be any appropriate anti-reflection coating for red light. In some embodiments, the anti-reflective coating may exhibit greater than 99% transmittance for light in the wavelength range of about 650 nm to about 850 nm. Preferably, the anti-reflective coating may exhibit greater than 99.9% transmittance for light in the wavelength range of about 650 nm to about 850 nm. The optical filter 650 may be disposed on an end surface of the lens 1825 assembly adjacent to the light pipe. In some embodiments, the red filter 1715 may also be highly reflective for light other than red light, such as green light. Such an optical filter may be a dichroic coating or multiple coatings with the desired cumulative optical properties. The optical filter may exhibit less than about 0.1% transmittance for light with a wavelength of less than about 600 nm. Preferably, the optical filter may exhibit less than about 0.01% transmittance for light with a wavelength of less than about 600 nm. In some embodiments, the optical excitation assembly 1700 comprises a lens assembly with green filter 1722. In some examples, light from the magneto-optical defect center material 1725 may be directed through the lens assembly with green filter 1722 to filter out light in the excitation band (in the red, for example), and to pass light in the green fluorescence band. The lens assembly with green filter 1722 may be any appropriate optical filter capable of transmitting green light and reflecting other light, such as red light. In some embodiments, the green filter may be a coating applied to an end surface of the lens assembly. The coating may be any appropriate anti-reflection coating for green light.

The filter(s) may be a coating formed by any appropriate method. In some embodiments, the filter(s) may be formed by an ion beam sputtering (IBS) process. The coating may be a single-layer coating or a multi-layer coating. The coating may include any appropriate material, such as magnesium fluoride, silica, hafnia, or tantalum pentoxide. The material for the coating may be selected based on the light pipe material and the material which the coating will be in contact with, such as an optical coupling material, to produce the desired optical properties. The coating may have a hardness that approximately matches the hardness of the light pipe. The coating may have a high density, and exhibit good stability with respect to humidity and temperature.

The optical excitation assembly 1700 comprises a magneto-optical defect center material 1725 with defect centers. In general, a variety of different magneto-optical defect center material, with a variety of magneto-optical defect centers can be used (e.g., diamond with nitrogen vacancy defect centers). Magneto-optical defect center materials include but are not be limited to diamonds, Silicon Carbide (SiC) and other materials with nitrogen, boron, or other defect centers.

In some embodiments, the optical excitation assembly 1700 may further comprise an accelerometer 1730, one or more thermistors 1735, a laser position adjustment flexure rib array 1740, and a laser angle adjustment flexure rib 1760. The optical excitation assembly 1700 comprises an optical excitation module 1745. The optical excitation module 1745 may be a directed light source. In some embodiments, the optical excitation module 1745 may be a light emitting diode. In some embodiments, the optical excitation module 1745 may be a laser diode.

The optical excitation assembly 1700 comprises an optical excitation focusing lens cell 1750. In some embodiments, the optical excitation focusing lens cell 1750 may be configured to focus light coming from the exit of a light pipe (e.g., a first light pipe 1705) on to a photo diode for collection.

The optical excitation assembly 1700 comprises a waveplate for laser polarization control 1755. The waveplate for laser polarization control 1755 may be, for example, the waveplate 315 described above. In some embodiments, the waveplate may be a half-wave plate. In some embodiments, the waveplate may be a quarter-wave plate. The waveplate may be configured to be rotated relative to the optical excitation assembly 1700 in order to change the polarization of the light (e.g., laser light). Examples of a waveplate design that may be used are described in U.S. patent application Ser. No. 15/468,274, filed on Mar. 24, 2017, the entire contents of which are incorporated by reference.

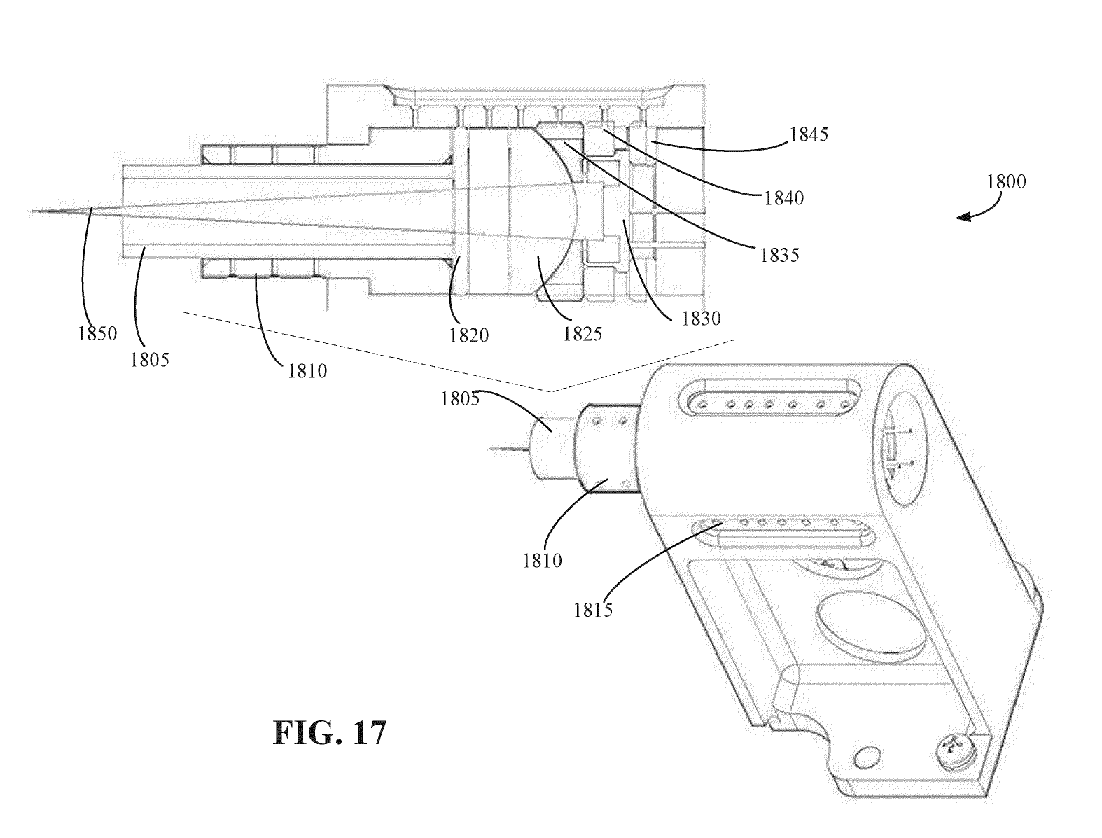

FIG. 17 depicts a light pipe with body mount 1800 illustrated in accordance with some embodiments. The figure also shows across section as viewed from above of a portion of body mount including the light pipe. The light pipe with body mount 1800 includes, in brief, a light pipe tube 1805 (e.g., hollow light pipe tube), a light pipe mount 1810, holes for staking optics for vibration 1815, one or more filters 1820, a lens 1825, a photo diode 1830, a lens retaining ring 1835, a photo diode mount 1840, and a photo diode retaining ring 1845. A representation of a light path 1850 is also shown.

The light pipe with body mount 1800 may comprise a light pipe tube 1805. In some embodiments, the light pipe tube 1805 may be configured to operably connect to an assembly for detecting red light or green light (e.g., using a photo diode 1830 configured to detect red light or green light). The light pipe tube 1805 may have any appropriate geometry. In some embodiments, the light pipe tube 1805 may be cylindrical and hollow. The hollow inside surface may be coated with a reflective surface. In some embodiments, the light pipe tube 1805 comprises a copper structure, silver inner reflective surface, and gold outer surface. A light pipe with such a structure may have approximately 95% reflection at a wavelength of light of 515 nm. In some embodiments, the reflection increases as the wavelength increases. In some embodiments, the light pipe tube 1805 may be configured to be mountable as outer points of the light pipe can be contacted without increasing emission loss from the light pipe. In some embodiments, the light pipe tube 1805 may have a circular cross-section, square cross-section, rectangular cross-section, hexagonal cross-section, or octagonal cross-section. In some embodiments, the light pipe tube 1805 may be a tubular piece of glass or metal (e.g., copper) that may be hollow on the inside and that has an inside surface coated with a reflective coating that directs light from the entrance side to the exit side such that the light pipe tube 1805 functions as a light pipe. The light pipe tube 1805 may be formed from any appropriate material (e.g., copper structure with reflective coatings).

The light pipe with body mount 1800 may comprise a light pipe mount 1810. The light pipe mount 1810 can be made of any material (e.g., plastic) that can hold the light pipe securely. Since, the performance of the hollow light pipe (e.g., light pipe tube 1805) is not diminished by contact or mounting points, the light pipe mount 1810 can be configured to hold the light pipe (e.g., light pipe tube 1805) securely. The light pipe with body mount 1800 may further comprise holes for staking optics for vibration 1815.

The light pipe with body mount 1800 may comprise one or more filters 1820. The filter(s) may be a coating formed by any appropriate method. In some embodiments, the filter(s) may be formed by an ion beam sputtering (IBS) process. The coating may be a single-layer coating or a multi-layer coating. The coating may include any appropriate material, such as magnesium fluoride, silica, hafnia, or tantalum pentoxide. The material for the coating may be selected based on the light pipe material and the material which the coating will be in contact with, such as an optical coupling material, to produce the desired optical properties. The coating may have a hardness that approximately matches the hardness of the light pipe. The coating may have a high density, and exhibit good stability with respect to humidity and temperature.

The light pipe with body mount 1800 may comprise a lens 1825. In some embodiments, the lens 1825 may be configured to focus light coming from the exit of a light pipe (e.g., light pipe tube 1805) on to a photo diode for collection. In some embodiments, the light pipe with body mount 1800 comprises a photo diode 1830. In some embodiments, the photo diode 1830 may be configured to collect light (e.g., red or green light collection). In some embodiments, the lens 1825 may be held in place by a lens retaining ring 1835 and the photo diode (e.g., photo diode 1830) may be held in place by a photo diode mount 1840 and photo diode retaining ring 1845. In some examples, an optical coupling material may be disposed between one or more of a light pipe, filter, magneto-optical defect material, photo diode, and lens as described in various embodiments. The optical coupling material may be any appropriate optical coupling material, such as a gel or epoxy. In some embodiments, the optical coupling material may be selected to have optical properties, such as an index of refraction, that improves the light transmission between the coupled components. The coupling material may be in the form of a layer formed between the components to be coupled. The optical coupling material may be configured to optically couple the light pipe to the magneto-optical defect center material. In some embodiments, the coupling material layer may have a thickness of about 1 micron to about 5 microns. The coupling material may serve to eliminate air gaps between the components to be coupled, increasing the light transmission efficiency. The coupling material may produce a light transmission between the components to be coupled that is functionally equivalent to direct contact between the components to be coupled. In some embodiments, an epoxy coupling material may also serve to mount the magneto-optical defect material to the optical waveguide assembly, such that other supports for material are not required. In some embodiments, a coupling material may not be necessary where direct contact between the optical filter or light pipe and the optical detector is achieved. Similarly, a coupling material may not be necessary where direct contact between the light pipe and the magneto-optical defect center material is achieved.

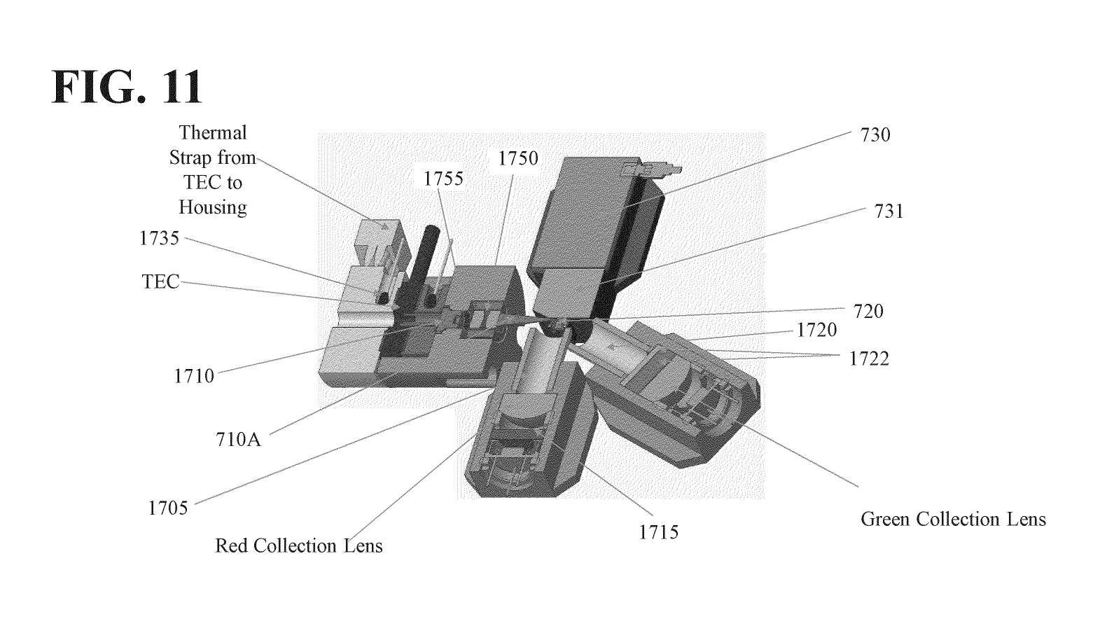

In order to reduce a size of the magnetometer 700, as illustrated in FIG. 11, the waveplate for laser polarization control 1755 may be incorporated into a housing of the photo diode 1710, 1810 or mounted to an output of the housing of the photo diode 1710, 1810. Moreover, the optical excitation focusing lens cell 1750 may include at least one microlens that is prealigned/prefabricated within the housing of the photo diode 1710, 1810 or at an output of the housing of the photo diode 1710, 1810. Microlenses have significantly smaller focal lengths, allowing the excitation light 710A (i.e., the diode output beam) to be shaped into a desired size within a much shorter distance, as compared to another type of lens.

Magnetic Field Generator

As described above, in an optical defect center based magnetometer (e.g., the magnetometer 700), a bias magnetic field may be used. However, if the magnetometer is used in environments that have a large temperature range, the bias magnetic field needs to be very stable over the operational temperature because the performance of the magnetometer may be directly related to the magnetic field strength. A stable operational temperature may be a predetermined temperature plus or minus a few degrees Celsius, preferably, plus or minus tenths of a degree Celsius, and even more preferably, plus or minus hundredths of a degree Celsius. Active cooling methods may be used to maintain the bias magnet and/or the entire magnetometer at the stable operational temperature. However, active cooling systems capable of maintaining the stable operational temperature are large in size, high in power consumption, heavy, control software and hardware intensive, and expensive.

The magnetic field generator 770 includes dual bias magnets that maintain the bias field uniformity even as the size of the magnetometer is reduced. For example, the magnetic field generator 770 includes a first bias magnet 771 provided within an upper portion of the interior of the shell portion 7100 and a second bias magnet 772 provided within a lower portion of the interior of the shell portion 7100 (see FIG. 8). Together, the first bias magnet 771 and the second bias magnet 772 may comprise a Helmholtz pair (i.e., a Helmholtz arrangement) placed symmetrically along a longitudinal axis of the housing 7000. The first bias magnet 771 may be provided above the individual components of the magnetometer 700 (e.g., the magneto-optical defect center material 720, the optical light system 710, the optical detector 740, etc.), while the second bias magnet 772 may be provided below the circuit board 760. In other words, one bias magnet may be provided on each side of the experimental area. By providing the first bias magnet 771 and the second bias magnet 772 in a Helmholtz arrangement, the z-axis uniformity of the magnetic field is improved such that even if the magnet size is reduced, the overall bias magnetic field uniformity, when averaged over the x-, y-, and z-axes, is not degraded.

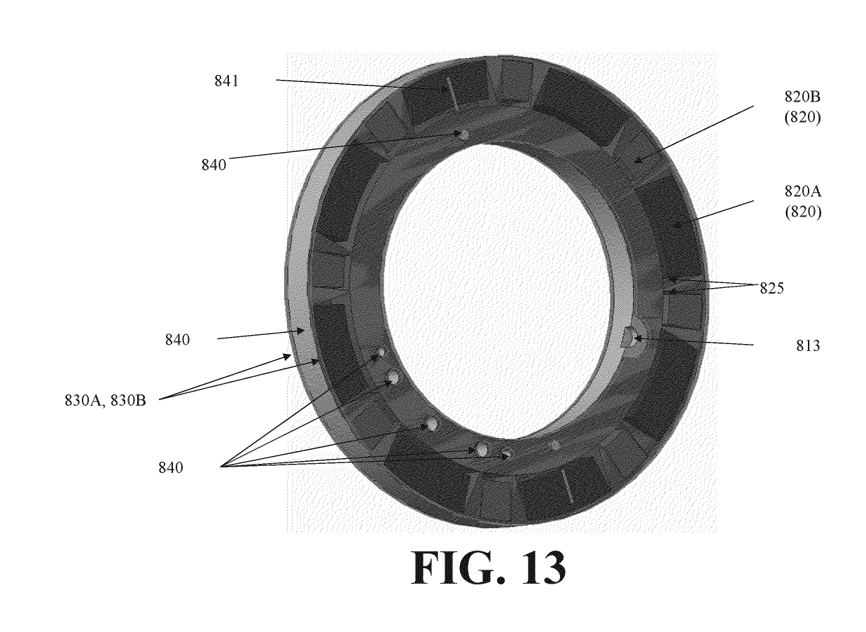

Each of the first bias magnet 771 and the second bias magnet 772 includes a mounting frame 810 configured to support a plurality of permanent magnets 820 (see FIG. 13). The mounting frame 810 may be made of plastic (e.g., Black Noryl ® PPO™, polystyrene, polyphenylene ether, etc.), titanium (e.g., Grade 5, Ti 6Al-4V, etc.), aluminum (e.g., 6061-T6 per ASTM B209, may have a chemical conversion coating per military standard MIL-DTL-5541, etc.), etc.

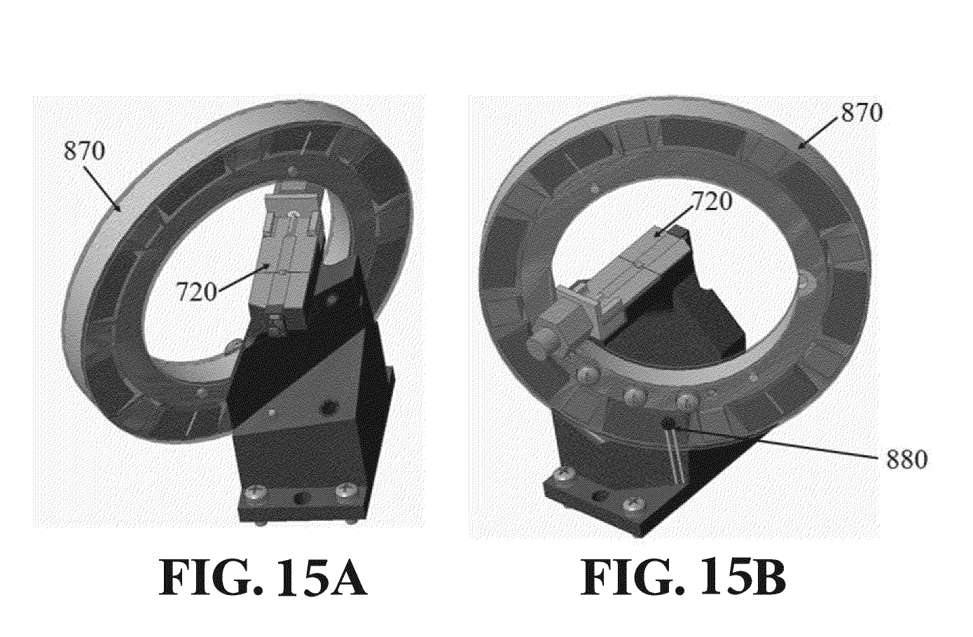

Referring to FIGS. 13-15B, in examples in which the housing 7000 is cylindrical, the mounting frame 810 may be circular and include a plurality of recesses 825 in a front side thereof arranged along a circumference thereof. Each of the recesses 825 may be sized and shaped to receive an arcuate permanent magnet 820. The sizes of the recesses 825 may be uniform (i.e., all of the permanent magnets 820 have the same size and shape) or non-uniform (i.e., at least one of the permanent magnets 820 has a different size and/or shape than another permanent magnet 820). Because the mounting frame 810 may be fabricated to include recesses corresponding to a particular arrangement of permanent magnets, the mounting frame 810 of FIGS. 13-15B may be a customized magnet frame configured for use in a particular magnetometer. The magnetic field generator of FIGS. 13-15B may be held together with structural epoxy. A first cover 830A and a second cover 830B may be provided on opposite sides of the mounting frame 810. Mutual attraction or repulsion between the permanent magnets 820 may occur. The first cover 830A and the second cover 830B are configured to provide a clamping force to help hold the permanent magnets 820 in place. One or more alignment pins 840 and one or more axis markers 841 may be provided along the mounting frame 810 to facilitate proper orientation of the magnetic field vector in the assembly. The first cover 830A, the second cover 830B and/or the alignment pins 840 may be made, for example, of aluminum. The mounting frame 810 may include one or more cutouts 813 along an interior periphery thereof. The cutouts 813 are configured to prevent the permanent magnets 820 from blocking the excitation light 710A generated by the optical light system 710. A thermistor 880 (FIG. 15B) may be epoxied (or otherwise attached) to one or more permanent magnets 820 to monitor a temperature thereof.

The permanent magnets 820 of FIGS. 13-15B are arranged in a Halbach array. One of ordinary skill in the art would understand that a Halbach array may be an arrangement of permanent magnets in which magnetic materials, for example, ferromagnetic materials, with alternating magnetizations are combined such that the magnetic fields align on one side of the Halbach array (e.g., above the plane of the magnetic materials), while the magnetic fields on the other side of the Halbach array (e.g., below the plane of the magnetic materials) are in opposite directions and cancel out in an ideal case. Because the ideal case may be never observed, a very small magnetic field may be produced on the other side of the Halbach array (e.g., below the plane of the magnetic materials).

The permanent magnets 820 of FIGS. 13-15B are comprised of one or more magnetic materials. In some examples, the permanent magnets 820 are comprised of two magnetic materials (i.e., a first magnetic material 820A and a second magnetic material 820B) such that the Halbach array may be a thermal compensated Halbach array configured to supply a stable bias magnetic field over large temperature ranges. As used herein, stable means that the magnetic field does not vary significantly over the timescale of a measurement. The primary driver for temporal changes in the magnetic field may be the change in the magnet's temperature. The metric of stability may either be the change in the field with respect to time [Tesla/s] or temperature [Tesla/K]. The latter may be more preferable in this context because the exact change in temperature vs. time may be a function of the magnetometer system. The first magnetic material 820A and the second magnetic material 820B are selected such that the magnetic materials have different temperature coefficients, and thus, have a different slope when plotting a change of magnetic field versus temperature. The first magnetic material 820A and the second magnetic material 820B are arranged such that a temperature coefficient of the magnetic materials are cancelled, and the magnetic fields generated by the magnetic field generator 870 are essentially independent with respect to the operational temperature of the magnetometer. The cancellation may be achieved, for example, by aligning the magnetic fields generated by each of the first magnetic material 820A and the second magnetic material 820B in the opposite direction. In some examples, the first magnetic material 820A generates a weaker magnetic field, but has a smaller slope when plotting the change of magnetic field versus temperature as compared to the magnetic field and slope of the second magnetic material 820B. The first magnetic material 820A may be oriented to produce a magnetic field in a desired direction (e.g., above the plane of the magnetic materials), while the second magnetic material 820B may be oriented to produce a magnetic field in a direction opposite to the desired direction (e.g., below the plane of the magnetic materials).

The magnetic field, B, produced by a permanent magnet with a temperature coefficient, c, varies a function of temperature follows:

B(Tₒ+ΔT)=B(Tₒ)[1−cΔT] (1)

where Tₒ is the initial temperature and ΔT is the change in temperature. In our configuration we have two opposing magnets with different coefficients c₁ and c₂. The total temperature dependent field produced by this configuration is:

Bₜₒₜₐₗ(Tₒ+ΔT)=B₁(Tₒ)[1−c₁ΔT]−B₂(Tₒ)[1−c₂ΔT] (2)

### At T=Tₒ:

Bₜₒₜₐₗ(Tₒ)=Bₒ=B₁(Tₒ)−B₂(Tₒ) (3)

To design a thermally stable magnet, set Bₜₒₜₐₗ(Tₒ+ΔT)=Bₒ, where Bₒ is the desired field and a constant with respect to temperature. Substituting Bₒ+B₂(Tₒ) for B₁(Tₒ) in (2) and solving for B₂(Tₒ) gives:

$${B}_{2} ( {T}_{o} ) = \frac{{c}_{1}}{{c}_{2} - {c}_{1}} {B}_{o} \qquad ( 4 )$$

Using equations (3) and (4), the values of B₁(Tₒ) and B₂(Tₒ) can be designed to produce a thermally stable field of Bₒ.

From equation (4) if c₂˜c₁ then B₂ will be very large with respect to B₁ or if c₁<<c₂ then B₂ will be very small with respect to B₁, neither of which may be ideal. The first magnetic material 820A may be comprised, for example, of Samarium Cobalt (e.g., SmCo30) and the second magnetic material 820B may be comprised, for example, of Neodymium (e.g., N52). The difference between SmCo and N52 may be in a range where reasonable values of B₁ and B₂ can be achieved. Other ferromagnetic materials such as alnico alloys (composed primary of aluminum, nickel and cobalt) may be used as the first magnetic material 820A or the second magnetic material 820B. Alternatively, the first magnetic material 820A or the second magnetic material 820B may be comprised of ferrous iron. Another factor to consider in selecting the magnetic materials may be whether the permanent magnets 820 are strong enough to fit within the small footprint desired. This may substantially limit the choice of magnetic materials. A further consideration may be that the maximum operating temperature must be significantly smaller than the Curie temperature such that the magnetic field strength changes linearly with temperature, although this may be less of a concern because Curie temperatures are typically quite high.

As illustrated in FIGS. 13-15B, the permanent magnets 820 comprised of the first magnetic material 820A and the second magnetic material 820B may be provided in an alternating fashion along a circumference of the mounting frame 810. For example, one permanent magnet 820 comprised of the first magnetic material 820A may be provided between two permanent magnets 820 comprised of the second magnetic material 820B, or one permanent magnet 820 comprised of the second magnetic material 820B may be provided between two permanent magnets 820 comprised of the first magnetic material 820A. Alternatively, one permanent magnet 820 comprised of the first magnetic material 820A may be provided between two permanent magnets comprised of the first magnetic material 820A or provided between one permanent magnet comprised of the first magnetic material 820A and one permanent magnet comprised of the second magnetic material 820B. Alternatively, one permanent magnet 820 comprised of the second magnetic material 820B may be provided between two permanent magnets comprised of the second magnetic material 820B or provided between one permanent magnet comprised of the first magnetic material 820A and one permanent magnet comprised of the second magnetic material 820B.

The sizes of the permanent magnets 820 in any of FIGS. 13-15B may be uniform or non-uniform. For example, when the sizes of the permanent magnets 820 are non-uniform, the permanent magnets 820 comprised of the first magnetic material 820A may be larger than the permanent magnets 820 comprised of the second magnetic material 820B. Alternatively, the permanent magnets 820 comprised of the first magnetic material 820A may be smaller than the permanent magnets 820 comprised of the second magnetic material 820B.

A number of permanent magnets 820 comprised of the first magnetic material and a number of permanent magnets 820 comprised of the second magnetic material may be the same or different in any of FIGS. 13-15B. For example, a number of permanent magnets 820 comprised of the first magnetic material may be greater than a number of permanent magnets 820 comprised of the second magnetic material. Alternatively, the number of permanent magnets 820 comprised of the first magnetic material may be less than a number of permanent magnets 820 comprised of the second magnetic material.

As noted above with respect to FIGS. 4 and 5, each of the dips (e.g., Lorentzians) in the graphs may correspond to one or more axes of the defect centers within the NV diamond material 620. The bias magnetic field applied to the magneto-optical defect center material 720 may adjust the order and orientation of the Lorentzian dips in the graphs. Accordingly, there are forty-eight unique orientations of the Lorentzians such that each Lorentzian is distinguishable from the others (e.g., as in the graph of FIG. 5). Thus, there are forty-eight unique positions of the permanent magnets 820 around the magneto-optical defect center material 720 corresponding to each of the forty-eight orientations of the Lorentzians.

In some illustrative examples, the mounting frame 810 may be movable such that twelve of the forty-eight positions of the magnets permanent magnets 820 are accessible. That is, the mounting frame 810 cannot be positioned into all of the forty-eight positions because the mounting frame 810 would interfere with the housing of the magnetometer, which may span across the top and bottom of the mounting frame 810. In some illustrative examples, the mounting frame 810 may be positioned such that the Lorentzians are distinguishable from one another and such that the light is not interfered with as it passes through the through-hole to the magneto-optical defect center material 720.

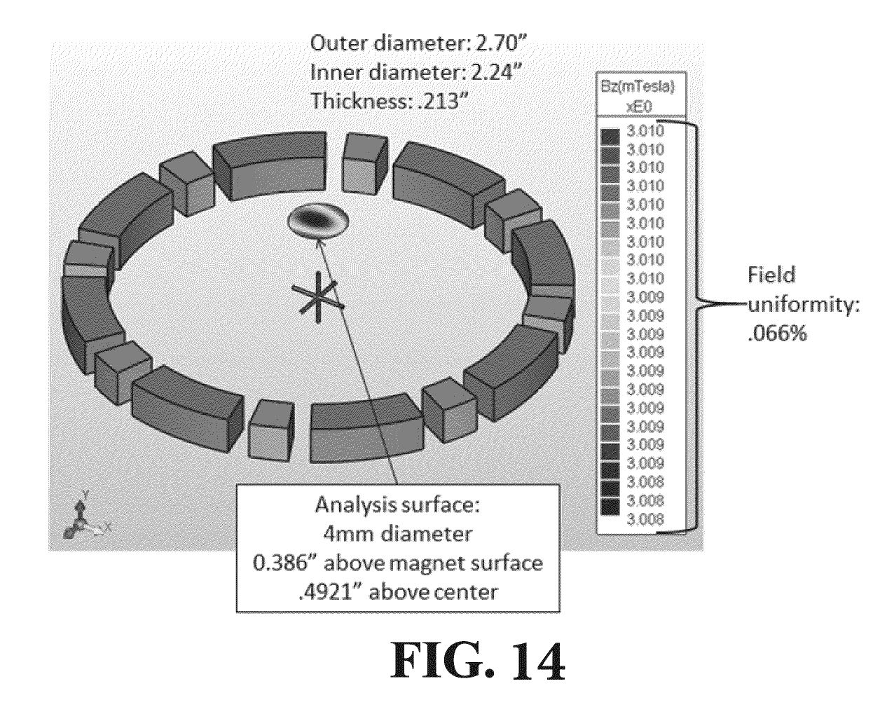

In some examples (see FIGS. 13-15B), the mounting frame 810 may be positioned such that the array of permanent magnets 820 are offset behind the magneto-optical defect center material 720. This creates a region having excellent magnetic field uniformity (see FIG. 14) in a plane of the magnetic field generator 870 that is centered on the magneto-optical defect center material 720. The dimensions included in FIG. 14 are non-limiting examples. Although this region provides excellent magnetic field uniformity in the x and y directions, the magnetic field may not be as uniform in the z direction. Therefore, in other examples, the mounting frame 810 may be positioned such that the array of permanent magnets 820 are not offset with respect to the magneto-optical defect center material 720. This orientation results in slightly less magnetic field uniformity in the x and y directions, but greater magnetic field uniformity in the z direction.

By providing a magnetic field generator 870 including the thermal compensated Halbach magnet arrays described above, it may be possible to supply a very stable bias magnetic field over large temperature ranges. In particular, use of the thermal compensated Halbach magnet arrays removes the need to control the magnet temperature to the levels required by a non-thermal-compensated magnet. For example, instead of requiring maintenance of a temperature in a range of the predetermined temperature plus or minus tenths of a degree Celsius over the full test time (e.g., on the order of several hours), a thermal compensated magnet may only require temperature control, for example, of 20 degrees Celsius over a one or two hour period. Thus, the cooling system for the magnet and/or the magnetometer may be passive or much smaller, simpler, lighter, lower power consuming, and cheaper than an active cooling system.

Size Reduction of Magnetometer

The complexity of the magnetometer makes it difficult to realize size reductions. RF amplification can have electromagnetic impacts on the optical collection. The bias magnet uniformity is reduced as the size is reduced. These issues negatively impact the performance of the magnetometer. These things must be overcome to realize a compact/small magnetometer with the same performance as a larger magnetometer.

An overall size of the magnetometer may be reduced by the following method: 1) reducing a size of each individual component, 2) utilizing a hermetically sealed housing that allows for elimination of purge gas systems/gaskets, 3) removing optical adjustment mechanisms from the interior of the housing of the magnetometer and adding the optical adjustment mechanisms to the tooling/fixturing used only during assembly of the magnetometer, 4) using a Helmholtz pair of bias magnets to maintain the bias field uniformity even as the size of the magnetometer is reduced, and/or 5) relying on unique optics for focusing and polarization of the laser diode to reduce a focal length between the laser and the magneto-optical defect center material, including using prealigned/prefabricated microlenses and incorporating a waveplate in the diode housing or at an output of the diode housing. The optical adjustment mechanisms may be configured to adjust components of the optical light system 710 (e.g., the laser, the lens cell, etc.) in three to five axes: x-axis, y-axis, z-axis, tip, and tilt. In particular, the optical adjustment mechanisms may be configured to adjust the location of the optical light system 710 such that the excitation light 710A is focused on the correct position on the magneto-optical defect center material 720 (x, y, z) and at a correct angle (tip/tilt).

The foregoing description is provided to enable a person skilled in the art to practice the various configurations described herein. While the subject technology has been particularly described with reference to the various figures and configurations, it should be understood that these are for illustration purposes only and should not be taken as limiting the scope of the subject technology. In some aspects, the subject technology may be used in various markets, including for example and without limitation, advanced sensors and mobile space platforms.

There may be many other ways to implement the subject technology. Various functions and elements described herein may be partitioned differently from those shown without departing from the scope of the subject technology. Various modifications to these examples may be readily apparent to those skilled in the art, and generic principles defined herein may be applied to other examples. Thus, many changes and modifications may be made to the subject technology, by one having ordinary skill in the art, without departing from the scope of the subj ect technology.

Phrases such as an aspect, the aspect, another aspect, some aspects, one or more aspects, an example, the example, another example, some examples, one or more examples, an embodiment, the embodiment, another embodiment, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases. Every combination of components described or exemplified can be used to practice the examples, unless otherwise stated. Some examples can be modified to incorporate any number of variations, alterations, substitutions or equivalent arrangements not heretofore described, but which are commensurate with the spirit and scope of the examples. Additionally, while various examples of the disclosure have been described, it is to be understood that aspects of the disclosure may include only some of the described examples. Accordingly, the disclosure is not to be seen as limited by the foregoing description.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various examples described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. Atty.

What is claimed is:

1. A magnetometer for magnetic detection, comprising:
a magneto-optical defect center material comprising at least one magneto-optical defect center that emits an optical signal when excited by an excitation light,
a radio frequency (RF) exciter system configured to provide RF excitation to the magneto-optical defect center material;
an optical excitation system configured to direct the excitation light to the magneto-optical defect center material, the optical excitation system including an optical light source;
an optical detector configured to receive the optical signal emitted by the magneto-optical defect center material based on the excitation light and the RF excitation;
a magnetic field generator configured to generate a magnetic field detected at the magneto-optical defect center material; and
a housing configured to enclose the magneto-optical defect center material, the RF exciter system, the optical excitation system, the optical detector, and the magnetic field generator,
wherein the housing is hermetically sealed.

2. The magnetometer of claim 1, wherein the housing comprises:
a shell portion;
a first lid fixed to an upper surface of the shell portion; and
a second lid fixed to a lower surface of the shell portion.

3. The magnetometer of claim 2, wherein the shell portion comprises a plurality of fins arranged along an outer perimeter of the shell portion, the one or more fins being configured to increase a surface area of the housing and facilitate natural convection cooling.

4. The magnetometer of claim 3, wherein the plurality of fins are arranged with equal spacing between adjacent fins.

5. The magnetometer of claim 2, wherein the shell portion, the first lid or the second lid is formed of a conductive or a semi-conductive material.

6. The magnetometer of claim 5, wherein the shell portion, the first lid or the second lid is formed of titanium, aluminum, copper or alloys thereof.

7. The magnetometer of claim 5, wherein the shell portion, the first lid or the second lid is formed of stainless steel, diamond, aluminum pyrolytic graphite or aluminum silicon carbide.

8. The magnetometer of claim 1, further comprising an optical waveguide assembly comprising an optical waveguide with a hollow core and at least one optical filter coating, wherein the optical waveguide assembly is configured to transmit light emitted from the magneto-optical defect center material to the optical detector through the at least one optical filter coating.

9. The magnetometer of claim 8, wherein the optical excitation system and the optical waveguide assembly are disposed within a diode housing.

10. The magnetometer of claim 8, wherein the optical excitation system is disposed within a diode housing, and the optical waveguide assembly is mounted to an output of the diode housing.

11. The magnetometer of claim 8, wherein the optical waveguide assembly comprises an optical excitation focusing lens cell configured to focus the excitation light from the optical light source.

12. The magnetometer of claim 11, wherein the optical excitation focusing lens cell comprises at least one microlens.

13. The magnetometer of claim 12, wherein
the optical excitation system and the optical waveguide assembly are disposed within a diode housing, and
the at least one microlens of the optical waveguide assembly is prefabricated within the diode housing.

14. The magnetometer of claim 12, wherein
the optical excitation system and the optical waveguide assembly are disposed within a diode housing, and
the at least one microlens of the optical waveguide assembly is prealigned within the diode housing.

15. The magnetometer of claim 1, wherein the magnetic field generator comprises a plurality of permanent magnets arranged in a Halbach array.

16. The magnetometer of claim 2, wherein
the magnetic field generator comprises a Halbach array comprised of a first mounting frame adjacent to the first lid fixed to the upper surface of the shell portion and a second mounting frame adjacent to the second lid fixed the lower surface of the shell portion, each of the first mounting frame and the second mounting frame configured to receive a plurality of permanent magnets therein, and
the magneto-optical defect center material, the RF exciter system, the optical excitation system, and the optical detector are provided between the first mounting frame and the second mounting frame.

17. The magnetometer of claim 16, wherein each of the first mounting frame and the second mounting frame includes a plurality of recesses along a circumference thereof, each recess configured to receive one of the permanent magnets.

18. The magnetometer of claim 16, wherein at least one of the permanent magnets is comprised of a first magnetic material and at least one of the permanent magnets is comprised of a second magnetic material different from the first magnetic material.

19. The magnetometer of claim 18, wherein the at least one of the permanent magnets comprised of the first magnetic material is larger in size than the at least one of the permanent magnets comprised of the second magnetic material.

20. The magnetometer of claim 18, wherein the first magnetic material comprises samarium cobalt and the second magnetic material comprises neodymium.

21. The magnetometer according to claim 1, wherein the magneto-optical defect center material comprises a nitrogen vacancy (NV) diamond material comprising at least one NV center.

22. The magnetometer according to claim 1, wherein the magneto-optical defect center material comprises a nitrogen vacancy (NV) diamond material comprising a plurality of NV centers.

23. A system for magnetic detection, comprising:
a magnetometer comprising:
a magneto-optical defect center material comprising at least one magneto-optical defect center that emits an optical signal when excited by an excitation light,
a radio frequency (RF) exciter system configured to provide RF excitation to the magneto-optical defect center material;
an optical excitation system configured to direct the excitation light to the magneto-optical defect center material, the optical excitation system including an optical light source;
an optical detector configured to receive the optical signal emitted by the magneto-optical defect center material based on the excitation light and the RF excitation;
a magnetic field generator configured to generate a magnetic field detected at the magneto-optical defect center material; and
a housing configured to enclose the magneto-optical defect center material, the RF exciter system, the optical excitation system, the optical detector, and the magnetic field generator, the housing being hermetically sealed;
optical adjustment mechanisms external to the housing, the optical adjustment mechanisms configured to adjust a position of the optical light source and/or the optical detector.

24. The system of claim 23, wherein the housing comprises:
a shell portion;
a first lid fixed to an upper surface of the shell portion; and
a second lid fixed to a lower surface of the shell portion.

25. The system of claim 24, wherein the shell portion comprises a plurality of fins arranged along an outer perimeter of the shell portion, the one or more fins being configured to increase a surface area of the housing and facilitate natural convection cooling.

26. The system of claim 25, wherein the plurality of fins are arranged with equal spacing between adjacent fins..

27. The system of claim 24, wherein the shell portion, the first lid or the second lid is formed of a conductive or a semi-conductive material.

28. The system of claim 27, wherein the shell portion, the first lid or the second lid is formed of titanium, aluminum, copper or alloys thereof

29. The system of claim 27, wherein the shell portion, the first lid or the second lid is formed of stainless steel, diamond, aluminum pyrolytic graphite or aluminum silicon carbide.

30. The system of claim 23, further comprising an optical waveguide assembly comprising an optical waveguide with a hollow core and at least one optical filter coating, wherein the optical waveguide assembly is configured to transmit light emitted from the magneto-optical defect center material to the optical detector through the at least one optical filter coating.

31. The system of claim 30, wherein the optical excitation system and the optical waveguide assembly are disposed within a diode housing.

32. The system of claim 30, wherein the optical excitation system is disposed within a diode housing, and the optical waveguide assembly is mounted to an output of the diode housing.

33. The system of claim 30, wherein the optical waveguide assembly comprises an optical excitation focusing lens cell configured to focus the excitation light from the optical light source.

34. The system of claim 33, wherein the optical excitation focusing lens cell comprises at least one microlens.

35. The system of claim 34, wherein
the optical excitation system and the optical waveguide assembly are disposed within a diode housing, and
the at least one microlens of the optical waveguide assembly is prefabricated within the diode housing.

36. The system of claim 34, wherein
the optical excitation system and the optical waveguide assembly are disposed within a diode housing, and
the at least one microlens of the optical waveguide assembly is prealigned within the diode housing.

37. The system of claim 23, wherein the magnetic field generator comprises a plurality of permanent magnets arranged in a Halbach array.

38. The system of claim 24, wherein
the magnetic field generator comprises a Halbach array comprised of a first mounting frame adjacent to the first lid fixed to the upper surface of the shell portion and a second mounting frame adjacent to the second lid fixed the lower surface of the shell portion, each of the first mounting frame and the second mounting frame configured to receive a plurality of permanent magnets therein, and
the magneto-optical defect center material, the RF exciter system, the optical excitation system, and the optical detector are provided between the first mounting frame and the second mounting frame.

39. The system of claim 38, wherein each of the first mounting frame and the second mounting frame includes a plurality of recesses along a circumference thereof, each recess configured to receive one of the permanent magnets.

40. The system of claim 38, wherein at least one of the permanent magnets is comprised of a first magnetic material and at least one of the permanent magnets is comprised of a second magnetic material different from the first magnetic material.

41. The system of claim 40, wherein the at least one of the permanent magnets comprised of the first magnetic material is larger in size than the at least one of the permanent magnets comprised of the second magnetic material.

42. The system of claim 40, wherein the first magnetic material comprises samarium cobalt and the second magnetic material comprises neodymium.

43. The system of claim 23, wherein the magneto-optical defect center material comprises a nitrogen vacancy (NV) diamond material comprising at least one NV center.

44. The system of claim 23, wherein the magneto-optical defect center material comprises a nitrogen vacancy (NV) diamond material comprising a plurality of NV centers.

45. A housing for a magnetometer including a magneto-optical defect center material, an RF exciter system, an optical excitation system, an optical detector, and a magnetic field generator, the housing comprising:
a shell portion;
a first lid fixed to an upper surface of the shell portion; and
a second lid fixed to a lower surface of the shell portion,
wherein the housing is hermetically sealed.

46. The housing of claim 45, wherein the shell portion comprises a plurality of fins arranged along an outer perimeter of the shell portion, the one or more fins being configured to increase a surface area of the housing and facilitate natural convection cooling.

47. The housing of claim 46, wherein the plurality of fins are arranged with equal spacing between adjacent fins..

48. The housing of claim 45, wherein the shell portion, the first lid or the second lid is formed of a conductive or a semi-conductive material.

49. The housing of claim 48, wherein the shell portion, the first lid or the second lid is formed of titanium, aluminum, copper or alloys thereof

50. The housing of claim 48, wherein the shell portion, the first lid or the second lid is formed of stainless steel, diamond, aluminum pyrolytic graphite or aluminum silicon carbide.

51. A magnetic field generator for a magnetometer including a magneto-optical defect center material, an RF exciter system, an optical excitation system, and an optical detector, the magnetic field generator comprising:
a plurality of permanent magnets arranged in a Halbach array.

52. The magnetic field generator of claim 51, wherein the Halbach array comprises:
a first mounting frame provided above the magneto-optical defect center material, the RF exciter system, the optical excitation system, and the optical detector; and
a second mounting frame provided below the magneto-optical defect center material, the RF exciter system, the optical excitation system, and the optical detector, each of the first mounting frame and the second mounting frame configured to receive a plurality of permanent magnets therein.

53. The magnetic field generator of claim 52, wherein each of the first mounting frame and the second mounting frame includes a plurality of recesses along a circumference thereof, each recess configured to receive one of the permanent magnets.

54. The magnetic field generator of claim 52, wherein at least one of the permanent magnets is comprised of a first magnetic material and at least one of the permanent magnets is comprised of a second magnetic material different from the first magnetic material.

55. The magnetic field generator of claim 54, wherein the at least one of the permanent magnets comprised of the first magnetic material is larger in size than the at least one of the permanent magnets comprised of the second magnetic material.

56. The magnetic field generator of claim 55, wherein the first magnetic material comprises samarium cobalt and the second magnetic material comprises neodymium.

57. An optical system for a magnetometer, the optical system comprising:
an optical excitation system configured to direct excitation light to a target, the optical excitation system including an optical light source; and
an optical waveguide assembly comprising an optical waveguide with a hollow core and at least one optical filter coating, wherein the optical waveguide assembly is configured to transmit light emitted from the target to an optical detector through the at least one optical filter coating,
wherein the optical excitation system and the optical waveguide assembly are disposed within a diode housing.

58. The optical system of claim 57, wherein the optical waveguide assembly comprises an optical excitation focusing lens cell configured to focus the excitation light from the optical light source.

59. The optical system of claim 58, wherein the optical excitation focusing lens cell comprises at least one microlens.

60. The optical system of claim 59, wherein the at least one microlens of the optical waveguide assembly is prefabricated within the diode housing.

61. The optical system of claim 59, wherein the at least one microlens of the optical waveguide assembly is prealigned within the diode housing.

62. An optical system for a magnetometer, the optical system comprising:
an optical excitation system configured to direct excitation light to a target, the optical excitation system including an optical light source; and
an optical waveguide assembly comprising an optical waveguide with a hollow core and at least one optical filter coating, wherein the optical waveguide assembly is configured to transmit light emitted from the target to an optical detector through the at least one optical filter coating,
wherein the optical excitation system is disposed within a diode housing, and the optical waveguide assembly is mounted to an output of the diode housing.

63. The optical system of claim 62, wherein the optical waveguide assembly comprises an optical excitation focusing lens cell configured to focus the excitation light from the optical light source.

64. The optical system of claim 63, wherein the optical excitation focusing lens cell comprises at least one microlens.

65. The optical system of claim 64, wherein the at least one microlens of the optical waveguide assembly is prefabricated at the output of the diode housing.

66. The optical system of claim 64, wherein the at least one microlens of the optical waveguide assembly is prealigned at the output of the diode housing.

67. A method for reducing a size a magnetometer including a magneto-optical defect center material, an RF exciter system, an optical excitation system, an optical detector, and a magnetic field generator, the method comprising:
reducing a size of the magneto-optical defect center material, the RF exciter system, the optical excitation system, the optical detector, and the magnetic field generator;
providing the magneto-optical defect center material, the RF exciter system, the optical excitation system, the optical detector, and the magnetic field generator within a hermetically sealed housing.

68. The method of claim 67, wherein
a position of the optical excitation system is adjusted via one or more optical adjustment mechanisms in one to five directions prior to providing the optical excitation system within the hermetically sealed housing,
all of the optical adjustment mechanisms are provided external to the hermetically sealed housing.

69. The method of claim 67, wherein
the magnetic field generator comprises a first mounting frame provided above the magneto-optical defect center material, the RF exciter system, the optical excitation system, and the optical detector, and a second mounting frame provided below the magneto-optical defect center material, the RF exciter system, the optical excitation system, and the optical detector, and
each of the first mounting frame and the second mounting frame is configured to receive a plurality of permanent magnets therein.

70. The method of claim 69, wherein the plurality of permanent magnets are arranged in a Halbach array.

71. The method of claim 67, wherein
the optical excitation system is configured to direct excitation light to a target, and
the optical excitation system includes an optical light source.

72. The method of claim 71, further comprising providing an optical waveguide assembly within the hermetically sealed housing, the optical waveguide assembly comprising an optical waveguide with a hollow core and at least one optical filter coating, wherein the optical waveguide assembly is configured to transmit light emitted from the target to an optical detector through the at least one optical filter coating,
wherein the optical excitation system and the optical waveguide assembly are disposed within a diode housing.

73. The method of claim 71, further comprising providing an optical waveguide assembly within the hermetically sealed housing, the optical waveguide assembly comprising an optical waveguide with a hollow core and at least one optical filter coating, wherein the optical waveguide assembly is configured to transmit light emitted from the target to an optical detector through the at least one optical filter coating,
wherein the optical excitation system is disposed within a diode housing, and the optical waveguide assembly is mounted to an output of the diode housing.
